(19) United States
(12) Patent Application Publication
(10) Pub. No.: US 2012/0281124 A1
(43) Pub. Date: Nov. 8, 2012

(54) SOLID-STATE IMAGING DEVICE, METHOD FOR DRIVING THE SAME, AND CAMERA

(75) Inventor: Sei SUZUKI, Osaka (JP)

(73) Assignee: PANASONIC CORPORATION, Osaka (JP)

(21) Appl. No.: 13/546,798

(22) Filed: Jul. 11, 2012

Related U.S. Application Data
(63) Continuation of application No. PCT/JP2010/006177, filed on Oct. 19, 2010.

(30) Foreign Application Priority Data
Jan. 12, 2010 (JP) 2010-004418

(51) Int. Cl. H01L 27/148; H04N 5/335

(52) U.S. Cl. 348/294; 250/208.1; 348/E05.091

(57) ABSTRACT

A solid-state imaging device according to the present invention includes: first vertical transfer units; transfer control units disposed in correspondence with the first vertical transfer units on m columns, and each configured to selectively transfer the signal charges transferred by any of the corresponding first vertical transfer units; and second vertical transfer units each configured to transfer the signal charges transferred by a corresponding one of the transfer control units. Each of the second vertical transfer units is disposed for horizontal transfer electrodes forming a transfer packet of a horizontal transfer unit and has a region in which a transfer width tapers from the corresponding one of the transfer control units toward the horizontal transfer unit. Moreover, each of the second vertical transfer units is provided with a vertical transfer electrode independent of vertical transfer electrodes of the first vertical transfer units and the transfer control units.

### CROSS REFERENCE TO RELATED APPLICATION

This is a continuation application of PCT Patent Application No. PCT/JP2010/006177 filed on Oct. 19, 2010, designating the United States of America, which is based on and claims priority of Japanese Patent Application No. 2010-004418 filed on Jan. 12, 2010. The entire disclosures of the above-identified applications, including the specifications, drawings and claims are incorporated herein by reference in their entirety.

### TECHNICAL FIELD

The present invention relates to solid-state imaging devices, methods for driving the solid-state imaging devices, and cameras, and, more particularly, to a solid-state imaging device which includes transfer control units for selectively transferring, to a horizontal transfer unit, signal charges transferred from any of a plurality of vertical transfer units.

### BACKGROUND ART

In recent years, CCDs (Charge Coupled Device) having 12M pixels or more are dominant as solid-state imaging devices for use in digital still cameras. An increase in number of pixels miniaturizes horizontal transfer electrodes included in the horizontal transfer unit, and increases the number of pixels in the horizontal direction to about 4,000. This arises a problem that inter-electrode capacitance dramatically increases in commonly-used two-phase drive systems in which one packet of the horizontal transfer unit is formed to one column of a first vertical transfer unit 1, ending up increased power consumption.

Thus, at present, a system is proposed in which the number of transfer packets of the horizontal transfer unit is not the same as the number of columns of vertical transfer units unlike conventional and is, for example, ⅓ of the number of columns of the vertical transfer units, an operation of transferring signal charges from the vertical transfer units to the horizontal transfer unit and from the horizontal transfer unit to an output unit is divided into three times to separate a line of signal charges to provide interlaced output (For example, see PTL 1).

The system allows reduction in number of electrodes included in the horizontal transfer unit. This reduces the inter-electrode capacitance, thereby achieving low power consumption.

However, in solid-state imaging devices having such a configuration, the number of packets of the horizontal transfer unit is less than the number of columns of the vertical transfer units. Thus, a transfer control unit which selectively controls transfer of the signal charges from the vertical transfer units to the horizontal transfer unit is required. Specifically, a function is required which retains the signal charges in the transfer control unit while the first transfer operation is being performed.

Moreover, at present, in addition to an imaging mode in which signals in a light receiving part are extracted as a still image (hereinafter, referred to as a normal mode), a video mode for LCD monitor display and video recording is used. In the video mode, in general, a method is used in which signal charges obtained from a plurality of pixels are summed in an image pick-up device or signal charges to be read out from the pixels are selectively decimated. This reduces the number of output signals, thereby achieving a video having a high frame rate. For example, in the video mode, the following output are achieved: a VGA output (640×480) achieving 30 frames/second; and a 720 p output (1280×720) supporting an HD format both in which the number of output signals are reduced from the number of pixels (10M, for example) outputted for a still image.

As described above, the frame rate is two to three frames/second in the normal mode. However, image output achieving 30 frames/second is required in the video mode. Therefore, in the video mode, it is necessary to compress the image close to 1/10 as compared to the number of pixels outputted for a still image. Thus, the number of signal charges to be summed increases.

Moreover, in the solid-state imaging devices for digital still cameras, in general, the Bayer array is used and adjacent signal charges having a same color are summed. In the solid-state imaging devices, the signal charges are summed in the vertical direction in the vertical transfer units or the horizontal transfer unit, and the signal charges are summed in the horizontal direction in the horizontal transfer unit.

The pixel summing in the vertical direction in the vertical transfer units can be achieved by providing a plurality of vertical transfer electrodes which read pixels from the photoelectric conversion unit to the vertical transfer units and devising the drive timing. On the other hand, to achieve the pixel summing in the horizontal direction, it is required to provide, between the vertical transfer units and the horizontal transfer unit, a transfer control unit for selectively controlling the transfer of the signal charges.

Moreover, one example of the video mode is described in PTL 2. In particular, a method for summing nine pixels, described in PTL 2, in which signal charges of three vertical pixels and three horizontal pixels are summed, is useful because the method causes no shift in center of gravity after the summing and can achieve a video having high quality images and less moire.

As described above, in the current solid-state imaging devices for digital cameras, the transfer control unit is required to achieve the low power consumption and provide a video which has a high frame rate utilizing the pixel summing.

Hereinafter, details of a conventional solid-state imaging device set forth in PTL 1 will be described.

FIG. 26 is a diagram showing a configuration of the conventional solid-state imaging device described in PTL 1. FIG. 27A to FIG. 27C show an operation of transferring signal charges in a normal mode. FIG. 28A to FIG. 28C show an operation of transferring signal charges when summing three horizontal pixels.

The solid-state imaging device shown in FIG. 26 includes the first vertical transfer units 1, a horizontal transfer unit 2, charge retention units 101, and VOG units 104. The charge retention units 101 each include a storage unit 102 and a hold unit 103.

An example of the operation of the solid-state imaging device having the configuration as set forth above will be described. In the example, the aforementioned transfer control unit is a region which includes the charge retention unit 101 and the VOG unit 104. Moreover, FIG. 26 shows an example in which the horizontal transfer unit 2 is of a three-phase drive. In the example, a group Gr includes adjacent three first vertical transfer units 1 in correspondence with a unit transfer bit of the horizontal transfer unit 2, and each group correspondingly has a VOG unit 104 which is a charge transfer unit.

The first vertical transfer units 1 transfer signal charges to the VOG unit 104 corresponding to the group Gr to which the first vertical transfer units 1 belong. Moreover, the VOG unit 104 transfers the signal charges to the unit transfer bit corresponding to the first vertical transfer units 1 from which the signal charges are transferred to the VOG unit 104. This allows any of the first vertical transfer units 1 of the group Gr to transfer the signal charges to the corresponding unit transfer bit via the VOG unit 104.

In the normal mode, as shown in FIG. 27A, signal charges on a column c indicated in FIG. 26 are transferred to the horizontal transfer unit 2 via the VOG unit 104 and then horizontally transferred to the output unit. During the transfer, the signal charges on columns a and b indicated in FIG. 26 are retained by the charge retention units 101 each of which include the storage unit 102 and a hold unit 103.

After the completion of transferring the signal charges on the column c, the signal charges on the column a are transferred, as shown in FIG. 27B, from the charge retention unit 101 to the horizontal transfer unit 2 and then transferred to the output unit. Last, as shown in FIG. 27C, the signal charges on the column b are transferred from the charge retention unit 101 to the horizontal transfer unit 2 and then transferred to the output unit.

That is, in the normal mode, a horizontal line of the signal charges is separated for every three signal charges and outputted.

On the other hand, in a mode of summing three horizontal pixels, as shown in FIG. 28A, the signal charges on the columns a and c are transferred to the horizontal transfer unit 2 via the VOG unit 104. Then, as shown in FIG. 28B, the signal charges on the columns a and c are transferred in the left direction for a unit of one group. Then, as shown in FIG. 28C, the signal charges on the column b are transferred to the horizontal transfer unit 2 via the VOG unit 104. This is how three pixels in the horizontal direction are summed.

In the mode of summing the three horizontal pixels, the number of signal charges after the summing match the number of packets of the horizontal transfer units 2, and thus there is no need to separate the line of signal charges for every three signal charges for transfer as in the normal mode.

Moreover, in both the normal mode and the mode of summing three horizontal pixels, transferring the signal charges from the first vertical transfer units 1 to the horizontal transfer units 2 is performed via the VOG unit 104, and the first vertical transfer units 1 are coupled to the VOG unit 104.

### CITATION LIST

### Patent Literature

[PTL 1] Japanese Unexamined Patent Application Publication No. 2006-310655
[PTL 2] Japanese Patent Publication No. 3848650

### SUMMARY OF INVENTION

### Technical Problem

However, in the conventional configuration described above, the plurality of first vertical transfer units is grouped at the VOG unit of the transfer control unit disposed above the horizontal transfer unit. Thus, upon transferring the signal charges from the VOG unit to the horizontal transfer unit, it is necessary that the vertical transfer units have shapes tapering toward horizontal transfer electrodes where the signal charges are received. If the tapering is too acute, the electric potential is shallow on the side of the horizontal transfer unit. This arises a problem that transfer degradations are present.

The present invention solves the above problems and an object of the present invention is to provide a solid-state imaging device which allows suppression of the transfer degradations in a configuration where a plurality of vertical transfer units is grouped, a method for driving the solid-state imaging device, and a camera.

### Solution to Problem

To achieve the objects described above, the solid-state imaging device according to one embodiment of the present invention includes: photoelectric conversion units disposed in rows and columns and configured to convert light into signal charges; first vertical transfer units disposed in one-to-one correspondence with the columns and each configured to transfer in a vertical direction the signal charges obtained by the photoelectric conversion units converting the light, the photoelectric conversion units being disposed on a corresponding one of the columns; and transfer control units disposed in correspondence with the first vertical transfer units on m columns successive in a horizontal direction, where m is an integer greater than or equal to 2, and each configured to selectively transfer the signal charges transferred by any of the corresponding first vertical transfer units on the m columns; second vertical transfer units disposed in correspondence with the transfer control units and each configured to transfer the signal charges transferred by a corresponding one of the transfer control units; and a horizontal transfer unit configured to transfer in the horizontal direction the signal charges transferred by the second vertical transfer units, wherein each of the second vertical transfer units is disposed for two or more horizontal transfer electrodes forming a transfer packet of the horizontal transfer unit and has a region in which a transfer width tapers from the corresponding one of the transfer control units toward the horizontal transfer unit, and each of the second vertical transfer units is provided with a vertical transfer electrode independent of vertical transfer electrodes of the first vertical transfer units and the transfer control units.

According to the above configuration, in the solid-state imaging device according to one embodiment of the present invention, since the second vertical transfer units each has a region in which a transfer width reduces from a corresponding transfer control unit to the horizontal transfer unit, the tapering of the vertical transfer unit on the side of the horizontal transfer unit can be set gradual, thereby preventing the electric potential from being shallow on the side of the horizontal transfer unit. Thus, the solid-state imaging device according to the present invention can suppress the transfer degradations.

Moreover, each of the transfer control units may include m of third vertical transfer units disposed in one-to-one correspondence with the m columns and each configured to transfer the signal charges transferred by the vertical transfer unit on a corresponding one of the m columns, and a distance, in the horizontal direction, between centers of m of the third vertical transfer units disposed adjacent to one another may be shorter than a distance, in the horizontal direction, between centers of the first vertical transfer units disposed adjacent to one another.

According to the above configuration, the solid-state imaging device according to one embodiment of the present invention can form a narrow width of the second vertical transfer unit in the horizontal direction. This allows the solid-state imaging device according to one embodiment of the present invention to set angles of tapering of the second vertical transfer units to be gentle. This allows the solid-state imaging device according to one embodiment of the present invention to suppress the transfer degradations due to a fact that the electric potential becomes shallower along with the transfer direction.

Moreover, each of the second vertical transfer units may include: a fourth vertical transfer unit configured to transfer the signal charges transferred by a corresponding one of the transfer control units and having a region in which a transfer width tapers from the corresponding one of the transfer control units toward the horizontal transfer unit; and a fifth vertical transfer unit configured to transfer to the horizontal transfer unit the signal charges transferred by the fourth vertical transfer unit and having a constant transfer width, and vertical transfer electrodes independent of each other may be disposed above the fourth vertical transfer unit and the fifth vertical transfer unit.

According to the above configuration, by providing the fourth vertical transfer unit and the fifth vertical transfer unit with independent electrodes, the solid-state imaging device according to one embodiment of the present invention allows reduced lengths of electrodes in the fourth vertical transfer unit. This allows the solid-state imaging device according to one embodiment of the present invention to ensure the transfer electric field, thereby suppressing transfer failure in the fourth vertical transfer unit.

Moreover, each of the transfer control units may include m of third vertical transfer units disposed in one-to-one correspondence with the m columns and each configured to transfer the signal charges transferred by the vertical transfer unit on a corresponding one of the m columns, a sixth vertical transfer unit which is one of the third vertical transfer units on the m columns may include a first vertical transfer electrode to which a same transfer pulse as a pulse applied to any of the vertical transfer electrodes of the first vertical transfer units is applied, and m−1 of the third vertical transfer units other than the sixth vertical transfer unit included in the third vertical transfer units on the m columns may each include a signal charge storage electrode and a transfer blocking electrode which are independent of the vertical transfer electrodes of the first vertical transfer units and the second vertical transfer units.

According to the above configuration, the solid-state imaging device according to one embodiment of the present invention allows reduction in number of independent electrodes in the transfer control units.

Moreover, the sixth vertical transfer unit may include the first vertical transfer electrode only.

According to the above configuration, the solid-state imaging device according to one embodiment of the present invention allows reduction in number of independent electrodes in the transfer control units.

Moreover, a transfer width of an entire region below the first vertical transfer electrode of the sixth vertical transfer unit may increase from the corresponding one of the first vertical transfer units toward a corresponding one of the second vertical transfer units.

According to the above configuration, the solid-state imaging device according to one embodiment of the present invention can improve the transfer electric field by utilizing narrow channel effects.

Moreover, a maximum transfer width of each of the second vertical transfer units may be larger than a width between outermost end portions of the first vertical transfer units disposed on outermost columns of the m columns.

According to the above configuration, the solid-state imaging device according to one embodiment of the present invention can establish deep electric potential at end portions, in the horizontal direction, of the second vertical transfer units as with the horizontally central portion thereof. This allows the solid-state imaging device according to one embodiment of the present invention to suppress bad transfer from the transfer control units to the second vertical transfer units.

Moreover, each of the first vertical transfer units may include a first n-type impurities-doped region and a second n-type impurities-doped region, the first n-type impurities-doped region may be formed in each of the first vertical transfer units, each of the transfer control units, each of the transfer control units, and the horizontal transfer unit, and the second n-type impurities-doped region may be formed in each of the first vertical transfer units and each of the transfer control units and is not formed in each of the second vertical transfer units and the horizontal transfer unit.

According to the above configuration, the solid-state imaging device according to one embodiment of the present invention can establish shallow electric potential of the second vertical transfer unit as compared to the case of forming the second vertical transfer unit using the same n-type impurity concentration as the first vertical transfer unit. Thus, the solid-state imaging device according to one embodiment of the present invention allows a large potential difference from the second vertical transfer unit to the horizontal transfer unit, thereby improving the transfer efficiency.

Moreover, a potential step may be formed in each of the second vertical transfer units so that electric potential on a side of a corresponding one of the transfer control units is shallower than electric potential on a side of the horizontal transfer unit.

According to the above configuration, the solid-state imaging device according to one embodiment of the present invention allows further improvement of the transfer efficiency of the second vertical transfer unit.

Moreover, a third n-type impurities-doped region may be formed in each of the second vertical transfer units on a side of the horizontal transfer unit to form the potential step.

According to the above configuration, the solid-state imaging device according to one embodiment of the present invention can suppress the reduction of a potential difference between the transfer control unit and the second vertical transfer unit due to the formation of the potential step. Thus, the transfer efficiency from the transfer control unit to the second vertical transfer unit can be improved.

Moreover, a p-type impurities-doped region may be formed in each of the second vertical transfer units on a side of a corresponding one of the transfer control units to form the potential step.

Moreover, a third n-type impurities-doped region may be further formed in each of the second vertical transfer units.

According to the above configuration, the solid-state imaging device according to one embodiment of the present invention can suppress the reduction of a potential difference between the transfer control unit and the second vertical transfer unit due to the formation of the potential step. Thus, the transfer efficiency from the transfer control unit to the second vertical transfer unit can be improved.

Moreover, a p-type impurities-doped region may be formed in each of the transfer control units.

According to the above configuration, the solid-state imaging device according to one embodiment of the present invention can establish shallow electric potential of the transfer control unit. Thus, the solid-state imaging device according to one embodiment of the present invention allows enhancement of the transfer electric field from the transfer control unit to the second vertical transfer unit, thereby improving the transfer efficiency.

Moreover, first vertical transfer electrodes of the first vertical transfer units, the transfer control units, and the second vertical transfer units, and the two or more horizontal transfer electrodes of the horizontal transfer unit may be formed of a single layer.

According to the above configuration, the solid-state imaging device according to one embodiment of the present invention can facilitate the wiring layout.

Moreover, a method for driving a solid-state imaging device, the method includes during a period for which signal charges on one of m columns are horizontally transferred, transferring to a fourth vertical transfer unit the signal charges on other column of the m columns from a transfer control unit corresponding to the other column, wherein the method is a method for driving the solid-state imaging device described above.

According to the above configuration, since the signal charges can be transferred from the transfer control unit to the fourth vertical transfer unit over a long period of time, utilizing the horizontal transfer period for another column, the signal charge transfer efficiency from the transfer control unit to the fourth vertical transfer unit can be improved.

Moreover, the method for driving the solid-state imaging device according to claim 15, the method may include: transferring to the fourth vertical transfer unit the signal charges on a center column, among the m columns, from the transfer control unit corresponding to the center column during a horizontal blanking period; and during a period for which the signal charges on the center column are transferred, transferring to the fourth vertical transfer unit the signal charges on an outermost column, among the m columns, from the transfer control unit corresponding to the outermost column.

According to the above configuration, the signal charge at end portions where the transfer failure is likely to occur can be transferred from the transfer control unit to the fourth vertical transfer unit over a long period of time. This allows suppression of transfer failure of the signal charges from the transfer control unit to the fourth vertical transfer unit.

Moreover, the camera according to one embodiment of the present invention includes the solid-state imaging device.

It should be noted that the present invention can be implemented as a semiconductor integrated circuit (LSI) achieving a part or the whole of the functionality of such a solid-state imaging device.

### Advantageous Effects of Invention

As described above, the present invention can provide a solid-state imaging device which allows suppression of transfer degradations in a configuration in which a plurality of vertical transfer units is grouped, a method for driving the solid-state imaging device, and a camera.

### BRIEF DESCRIPTION OF DRAWINGS

These and other objects, advantages and features of the invention will become apparent from the following description thereof taken in conjunction with the accompanying drawings that illustrate a specific embodiment of the present invention. In the Drawings:

FIG. 1 is a top view of a solid-state imaging device according to an embodiment 1 of the present invention;

FIG. 2A is a diagram showing an operation by the solid-state imaging device according to the embodiment 1 of the present invention in a normal mode;

FIG. 2B is a diagram showing an operation by the solid-state imaging device according to the embodiment 1 of the present invention in the normal mode;

FIG. 2C is a diagram showing an operation by the solid-state imaging device according to the embodiment 1 of the present invention in the normal mode;

FIG. 2D is a diagram showing an operation by the solid-state imaging device according to the embodiment 1 of the present invention in the normal mode;

FIG. 3 is a diagram showing drive timing by the solid-state imaging device according to the embodiment 1 of the present invention in the normal mode;

FIG. 4A is a diagram showing an operation by the solid-state imaging device according to the embodiment 1 of the present invention when summing three horizontal pixels;

FIG. 4B is a diagram showing an operation by the solid-state imaging device according to the embodiment 1 of the present invention when summing three horizontal pixels;

FIG. 4C is a diagram showing an operation by the solid-state imaging device according to the embodiment 1 of the present invention when summing three horizontal pixels;

FIG. 5 is a diagram showing drive timing by the solid-state imaging device according to the embodiment 1 of the present invention in summing three horizontal pixels;

FIG. 6A is a top view of modification of the solid-state imaging device according to the embodiment 1 of the present invention;

FIG. 6B is a top view of modification of the solid-state imaging device according to the embodiment 1 of the present invention;

FIG. 7 is a top view of modification of the solid-state imaging device according to the embodiment 1 of the present invention;

FIG. 8A is a top view of a first example of the solid-state imaging device according to the embodiment 1 of the present invention;

FIG. 8B is a sectional view of the first example the solid-state imaging device according to the embodiment 1 of the present invention;

FIG. 8C is a diagram showing potential distribution of the first example of the solid-state imaging device according to the embodiment 1 of the present invention;

FIG. 9A is a top view of a second example of the solid-state imaging device according to the embodiment 1 of the present invention;

FIG. 9B is a sectional view of the second example of the solid-state imaging device according to the embodiment 1 of the present invention;

FIG. 9C is a diagram showing potential distribution of the second example of the solid-state imaging device according to the embodiment 1 of the present invention;

FIG. 10 is a diagram comparing the first example and the second example of the solid-state imaging device according to the embodiment 1 of the present invention;

FIG. 11A is a sectional view of a third example of the solid-state imaging device according to the embodiment 1 of the present invention;

FIG. 11B is a diagram showing potential distribution of the third example of the solid-state imaging device according to the embodiment 1 of the present invention;

FIG. 12 is a top view of a fourth example of the solid-state imaging device according to the embodiment 1 of the present invention;

FIG. 13 is a diagram comparing the third example and the fourth example of the solid-state imaging device according to the embodiment 1 of the present invention;

FIG. 14A is a sectional view of a fifth example of the solid-state imaging device according to the embodiment 1 of the present invention;

FIG. 14B is a diagram showing potential distribution of the fifth example of the solid-state imaging device according to the embodiment 1 of the present invention;

FIG. 15A is a sectional view of a sixth example of the solid-state imaging device according to the embodiment 1 of the present invention;

FIG. 15B is a diagram showing potential distribution of the sixth example of the solid-state imaging device according to the embodiment 1 of the present invention;

FIG. 16A is a sectional view of a seventh example of the solid-state imaging device according to the embodiment 1 of the present invention;

FIG. 16B is a sectional view of an eighth example of the solid-state imaging device according to the embodiment 1 of the present invention;

FIG. 16C is a diagram showing potential distributions of the seventh example and the eighth example of the solid-state imaging device according to the embodiment 1 of the present invention;

FIG. 17A is a sectional view of a ninth example of the solid-state imaging device according to the embodiment 1 of the present invention;

FIG. 17B is a diagram showing potential distribution of the ninth example of the solid-state imaging device according to the embodiment 1 of the present invention;

FIG. 18 is a top view of a the solid-state imaging device according to an embodiment 2 of the present invention;

FIG. 19 is a top view of the solid-state imaging device according to an embodiment 3 of the present invention;

FIG. 20 is a diagram showing drive timing by the solid-state imaging device according to the embodiment 3 of the present invention in summing three horizontal pixels;

FIG. 21 is a diagram showing drive timing by a solid-state imaging device according to an embodiment 4 of the present invention in summing three horizontal pixels;

FIG. 22 is a top view of a solid-state imaging device according to an embodiment 5 of the present invention;

FIG. 23A is a diagram showing an operation by the solid-state imaging device according to the embodiment 5 of the present invention in a normal mode;

FIG. 23B is a diagram showing an operation by the solid-state imaging device according to the embodiment 5 of the present invention in the normal mode;

FIG. 23C is a diagram showing an operation by the solid-state imaging device according to the embodiment 5 of the present invention in the normal mode;

FIG. 23D is a diagram showing an operation by the solid-state imaging device according to the embodiment 5 of the present invention in the normal mode;

FIG. 23E is a diagram showing an operation by the solid-state imaging device according to the embodiment 5 of the present invention in the normal mode;

FIG. 24 is a diagram showing drive timing by the solid-state imaging device according to the embodiment 5 of the present invention, with regard to distribution transfer of signal charges between horizontal transfer units;

FIG. 25A is a diagram showing an operation by the solid-state imaging device according to the embodiment 5 of the present invention when summing two horizontal pixels;

FIG. 25B is a diagram showing an operation by the solid-state imaging device according to the embodiment 5 of the present invention when summing two horizontal pixels;

FIG. 25C is a diagram showing an operation by the solid-state imaging device according to the embodiment 5 of the present invention when summing two horizontal pixels;

FIG. 26 is a top view of the conventional solid-state imaging device;

FIG. 27A is a diagram showing an operation by the conventional solid-state imaging device in a normal mode;

FIG. 27B is a diagram showing an operation by the conventional solid-state imaging device in the normal mode;

FIG. 27C is a diagram showing an operation by the conventional solid-state imaging device in the normal mode;

FIG. 28A is a diagram showing an operation by the conventional solid-state imaging device when summing three horizontal pixels;

FIG. 28B is a diagram showing an operation by the conventional solid-state imaging device when summing three horizontal pixels; and

FIG. 28C is a diagram showing an operation by the conventional solid-state imaging device when summing three horizontal pixels.

### DESCRIPTION OF EMBODIMENTS

Hereinafter, embodiments of the present invention will be described with accompanying drawings.

### Embodiment 1

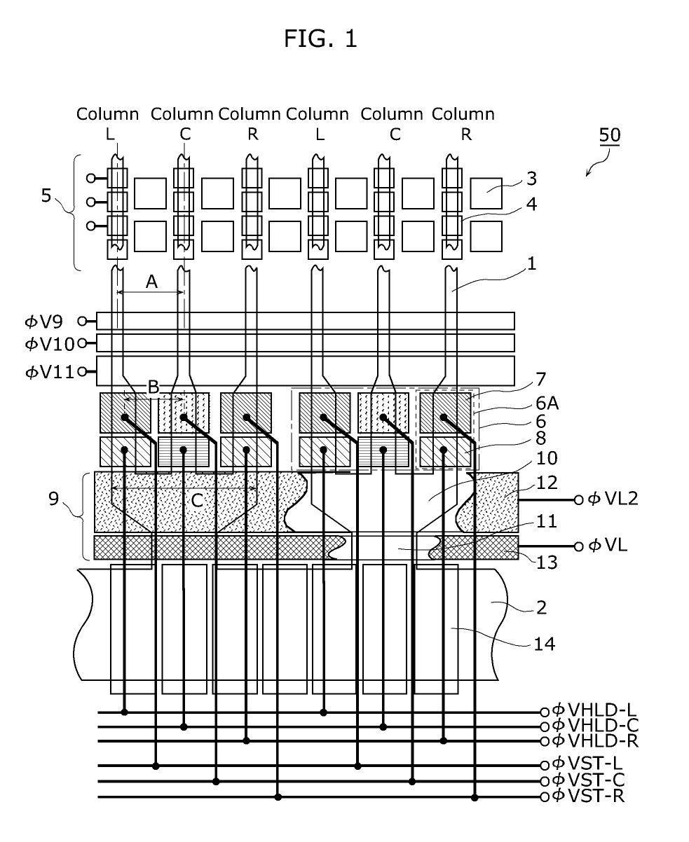

FIG. 1 is a diagram showing a configuration of a solid-state imaging device 50 according to an embodiment 1 of the present invention.

The solid-state imaging device 50 shown in FIG. 1 includes a pixel repetition unit 5, a plurality of transfer control units 6, a plurality of second vertical transfer units 9, a horizontal transfer unit 2, and a plurality of horizontal transfer electrodes 14.

The pixel repetition unit 5 includes a plurality of photo-electric conversion units 3, a plurality of first vertical transfer units 1, and a plurality of first vertical transfer electrodes 4.

The plurality of photo-electric conversion units 3 is disposed in rows and columns, convert light into signal charges, and store the resultant signal charges therein.

The plurality of first vertical transfer units 1 is disposed in correspondence with respective columns, and each transfer the signal charges in the vertical direction which are obtained by the plurality of photo-electric conversion units 3, disposed on a corresponding column, converting the light.

The plurality of first vertical transfer electrodes 4 is formed above the plurality of first vertical transfer units 1.

The plurality of transfer control units 6 are each disposed for every m (m is an integer greater than or equal to 2) columns of the first vertical transfer units 1 successive in the horizontal direction, among the plurality of first vertical transfer units 1. Each transfer control unit 6 selectively transfers the signal charges transferred by corresponding any of the first vertical transfer units 1 on the m columns.

Each transfer control unit 6 includes m third vertical transfer units 6A each of which is disposed in one-to-one correspondence with each of the m columns and transfers the signal charges transferred by the first vertical transfer unit 1 on a corresponding column, m signal charge storage electrodes 7, and m transfer blocking electrodes 8.

The third vertical transfer unit 6A is disposed in one-to-one correspondence with each of the m columns to which the transfer control unit 6 corresponds. The third vertical transfer unit 6A transfers the signal charges transferred by the first vertical transfer unit 1 on a corresponding column.

The signal charge storage electrode 7 and the transfer blocking electrode 8 are formed above each third vertical transfer unit 6A.

The second vertical transfer unit 9 is disposed in one-to-one correspondence with each transfer control unit 6 and transfers the signal charges transferred by the corresponding transfer control unit 6. Moreover, the second vertical transfer unit 9 is disposed for every two or more horizontal transfer electrodes 14 which form one transfer packet of the horizontal transfer unit 2. Moreover, the second vertical transfer unit 9 has a region in which the transfer width reduces from the transfer control unit 6 toward the horizontal transfer unit 2. Moreover, the second vertical transfer unit 9 is provided with vertical transfer electrodes independent of the vertical transfer electrodes of the first vertical transfer unit 1 and the transfer control unit 6.

The second vertical transfer unit 9 includes a fourth vertical transfer unit 10, a fifth vertical transfer unit 11, a fourth vertical transfer electrode 12, and a vertical final electrode 13.

The fourth vertical transfer unit 10 transfers the signal charges transferred by the transfer control unit 6. Moreover, the fourth vertical transfer unit 10 has a region in which the transfer width reduces from the transfer control unit 6 toward the horizontal transfer unit 2.

The fifth vertical transfer unit 11 transfers the signal charges transferred by the fourth vertical transfer unit 10. Moreover, the fifth vertical transfer unit 11 has a fixed transfer width and is disposed straightforward in the horizontal direction.

The horizontal transfer unit 2 transfers, in the horizontal direction, the signal charges transferred by the second vertical transfer unit 9. The plurality of horizontal transfer electrodes 14 is formed above the horizontal transfer unit 2. Moreover, the horizontal transfer unit 2 transfers, to an output unit (not shown) included in the solid-state imaging device 50, the signal charges transferred by the second vertical transfer units 9.

The output unit converts the signal charges transferred thereto by the horizontal transfer unit 2 into voltage signals, and outputs the resultant voltage signals to outside.

In the embodiment 1 of the present invention, the second vertical transfer unit 9 groups three columns of the first vertical transfer units 1. Moreover, one unit transfer packet of the horizontal transfer unit 2 corresponds to one second vertical transfer unit 9. That is, the number of unit transfer packets of the horizontal transfer unit 2 is ⅓ of the number of columns of the first vertical transfer units 1. Thus, to output a line of the signal charges without summing, the signal charges are separated for every three signal charges to be outputted (horizontal 3:1 interlace).

Moreover, in FIG. 1, an example is given in which the horizontal transfer unit 2 is of a four-phase drive in units of four horizontal transfer electrodes 14. That is, transfer pulses φH1, φH2, φH3, and φH4 are applied to the horizontal transfer electrodes 14. As described below, the horizontal transfer unit 2 may be of a three-phase drive in units of three horizontal transfer electrodes 14 or of two-phase drive in units of two horizontal transfer electrodes 14.

The four-phase drive allows reduction in length of the horizontal transfer electrodes 14 in a transfer direction as compared to the three-phase drive shown in the conventional example, and thus has advantages that a low voltage drive is possible. For example, if the size of pixels is about 1.5 μm, the use of the four-phase drive allows 1.8 V drive. The voltage 1.8 V is used also in other semiconductor devices incorporated in digital still cameras, and thus is advantageous as being easy to handle when designing cameras.

Moreover, as set forth in the description of Background Art, in the case of employing the horizontal interlace, an operation of retaining the signal charges during the horizontal transfer period is necessary. In particular, in the case of retaining the signal charges by one electrode (the signal charge storage electrode 7 in the present embodiment), it is required to reserve a necessary amount of saturation charges by increasing the length of the electrode storing the signal charges and/or increasing the width of the first vertical transfer unit 1 below the electrode in the horizontal direction larger than the width of the first vertical transfer unit 1 of the pixel repetition unit 5.

Merely increasing the lengths of the electrode reduces the transfer electric field, ending up undesirably reducing the transfer efficiency. Thus, it is desirable to increase the width of the first vertical transfer unit 1 to reserve the amount of saturation charges. For example, in FIG. 1, the width of the third vertical transfer units 6A in the horizontal direction in the transfer control unit 6 is larger than the width of the first vertical transfer units 1 in the horizontal direction in the pixel repetition unit 5.

A first feature of the solid-state imaging device 50 according to the embodiment 1 of the present invention is that the second vertical transfer units 9 each have a region in which a transfer width reduces from the transfer control unit 6 toward the horizontal transfer unit 2. This produces gentle tapering of the second vertical transfer units 9 on a side of the horizontal transfer unit 2, thereby preventing the electric potential from being shallow on the side of the horizontal transfer unit 2. Thus, the solid-state imaging device 50 allows suppression of the transfer degradations.

A second feature of the solid-state imaging device 50 is that three columns of the third vertical transfer units 6A in the transfer control unit 6 are disposed so as to have shorter repetition pitches therebetween than repetition pitches between the first vertical transfer units 1 of the pixel repetition unit 5. That is, in FIG. 1, given that, in the pixel repetition unit 5, a distance between the center of the first vertical transfer unit 1 in the horizontal direction and the center of an adjacent first vertical transfer unit 1 in the horizontal direction is represented by A and a distance between the centers of the third vertical transfer units 6A which are disposed in the horizontal direction adjacent to one another and included in each transfer control unit 6, is represented by B, relationship between A and B satisfies A>B.

This allows the solid-state imaging device 50 to form a width C of the fourth vertical transfer unit 10 in the horizontal direction to be narrow. Thus, the fourth vertical transfer unit 10 needs to taper along with the transfer direction for transferring the signal charges to the horizontal transfer unit 2, but there is an advantage that the angle of tapering can be set gentle. This allows the solid-state imaging device 50 to suppress undesirable effects in causing the electric potential to be shallower along with the transfer direction.

A third feature of the solid-state imaging device 50 is that the fourth vertical transfer unit 10 and the fifth vertical transfer unit 11 are provided with the fourth vertical transfer electrode 12 and the vertical final electrode 13, respectively, as independent electrodes. Moreover, since the transfer width of the fourth vertical transfer unit 10 tapers along with the transfer direction, the electric potential becomes shallower toward the side of the horizontal transfer unit 2. However, providing the fourth vertical transfer unit 10 and the fifth vertical transfer unit 11 with the fourth vertical transfer electrode 12 and the vertical final electrode 13, respectively, as independent electrodes shortens the electrode lengths. This ensures the transfer electric field, and thus suppression of the transfer failure in the fourth vertical transfer unit 10 is possible.

A fourth feature of the present embodiment is that a potential step is formed in the fourth vertical transfer unit 10 included in the second vertical transfer unit 9 so that an electric potential on a side of the transfer control unit 6 is shallower than an electric potential on a side of the horizontal transfer unit 2. For example, an n-type impurities-doped region is formed in the fourth vertical transfer unit 10 in consideration with the transfer efficiency, so that the electric potential of the fourth vertical transfer unit 10 on the side of the transfer control unit 6 is shallow. This allows further improvement in transfer efficiency of the fourth vertical transfer unit 10. The details will be described below.

A fifth feature of the solid-state imaging device 50 is that the n-type impurity concentration of the second vertical transfer unit 9 is lower than n-type impurity concentrations of the pixel repetition unit 5 and the transfer control unit 6. Specifically, the first vertical transfer unit 1 is formed of, for example, two n-type diffusion layers to suppress reduction in handling quantity of electric charges and the transfer efficiency degradation that are due to narrow channel effects in the pixel repetition unit 5 and to ensure, using one electrode, necessary handling quantity of electric charges in the transfer control unit 6. Moreover, either one of the two n-type diffusion layers that are used for forming the pixel repetition unit 5 is used as an n-type diffusion layer of the second vertical transfer unit 9.

This allows formation of a shallow electric potential of the second vertical transfer unit 9 as compared to the case of forming the second vertical transfer unit 9 using a same n-type impurity concentration as the pixel repetition unit 5. Thus, a large potential difference from the fifth vertical transfer unit 11 to the horizontal transfer unit 2 is possible, thereby improving the transfer efficiency. Details of the configuration will be described below.

A sixth feature of the present embodiment is that the n-type impurities-doped region is provided in the second vertical transfer unit 9 while n-type impurity concentration of the n-type impurities-doped region is lower than n-type impurity concentrations of the pixel repetition unit 5 and the transfer control unit 6 which are cited as the fifth feature. This increases a potential difference between the transfer control unit 6 and the fourth vertical transfer unit 10, thereby improving transfer efficiency at the transfer control unit 6 and the fourth vertical transfer unit 10. Alternatively, the p-type impurities-doped region is provided in the transfer control unit 6 while the n-type impurity concentration in the second vertical transfer unit 9 is low, so that the electric potential of the transfer control unit 6 is shallower than the electric potential when the pixel repetition unit 5 is expanded in the horizontal direction. This allows a large potential difference between the transfer control unit 6 and the fourth vertical transfer unit 10, thereby improving the transfer efficiency at the transfer control unit 6 and the fourth vertical transfer unit 10.

In the solid-state imaging device 50, transfer pulses φVST-L, φVST-C, and φVST-R are applied to the signal charge storage electrodes 7. Moreover, transfer pulses φVHLD-L, φVHLD-C, and φVHLD-R are applied to the transfer blocking electrodes 8. In FIG. 1, among the transfer control units 6 in units of three columns, a column to which φVST-C and φVHLD-C are applied is a column C, a column to which φVST-R and VHLD-R are applied is a column R, and a column to which φVST-L and φHLD-L are applied is a column L. Moreover, a transfer pulse φVL2 is applied to the fourth vertical transfer electrode 12 and a transfer pulse φVL is applied to the vertical final electrode 13.

Hereinafter, an operation of the solid-state imaging device 50 configured as described above will be described.

First, an operation of the solid-state imaging device 50 in a normal mode will be described.

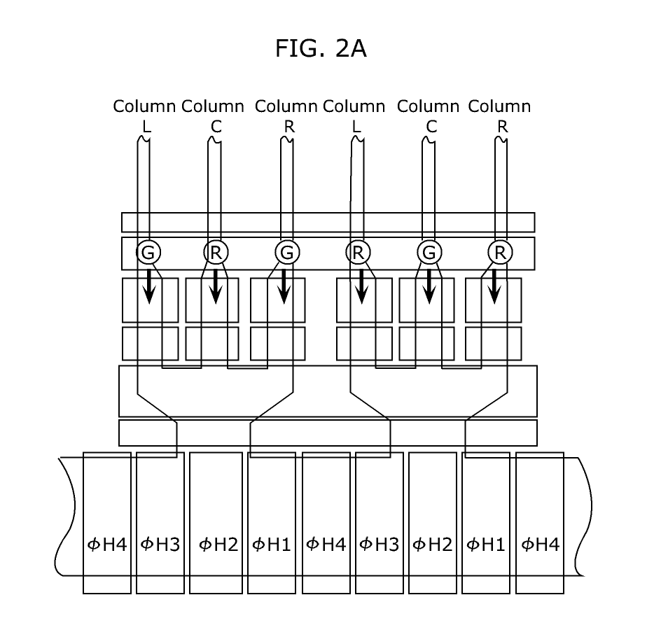

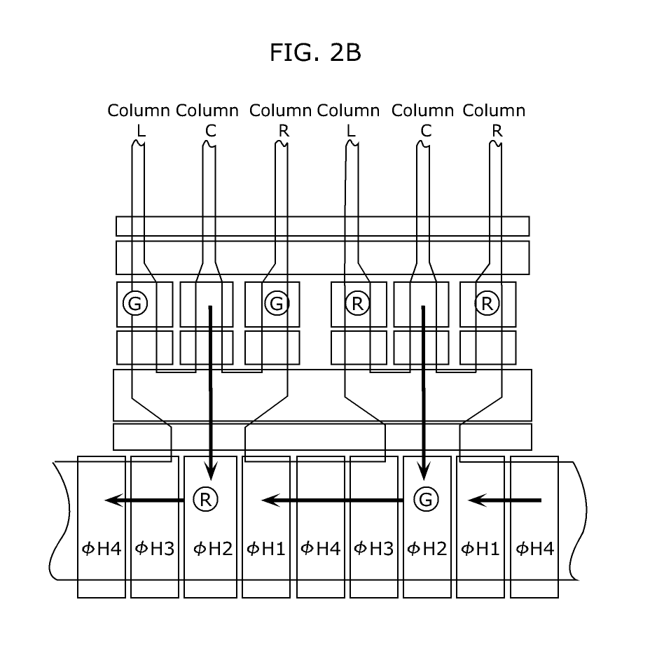

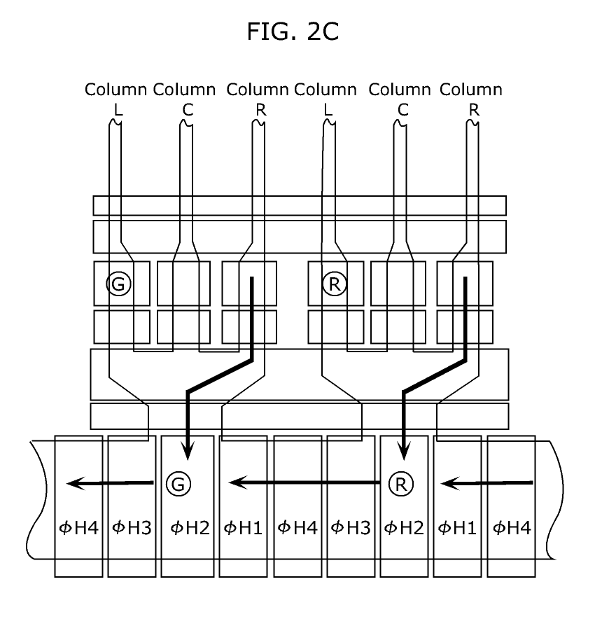

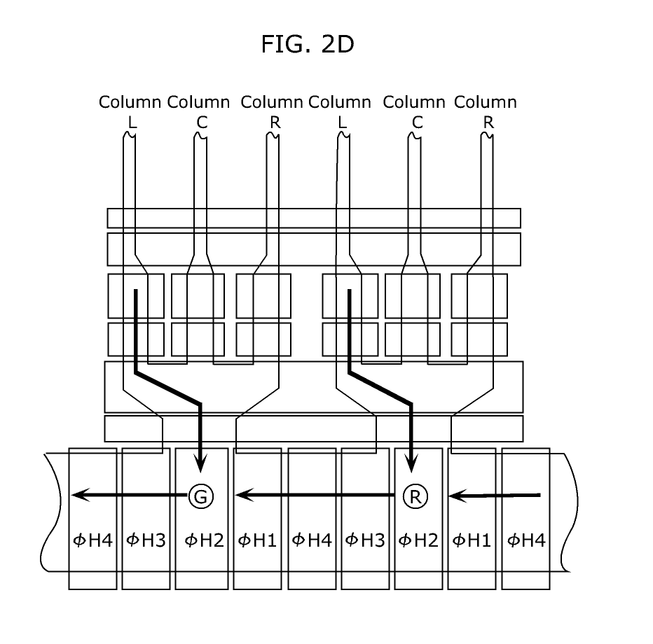

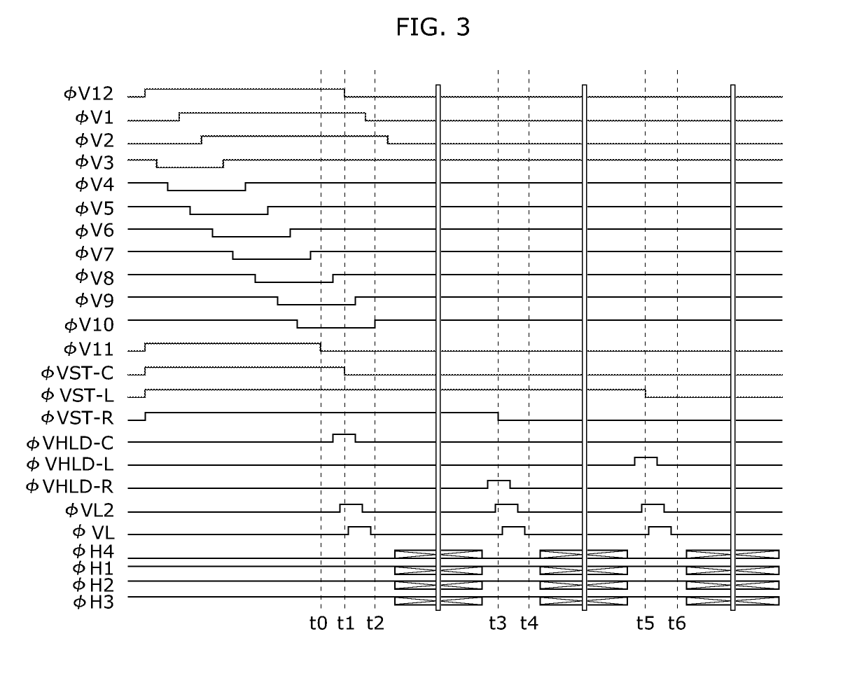

FIG. 2A to FIG. 2D are diagrams showing transfer of the signal charges by the solid-state imaging device 50 in the normal mode. Moreover, FIG. 3 is a timing diagram showing drive timing in the normal mode.

As shown in FIG. 2A to FIG. 2D, since the number of packets of the horizontal transfer unit 2 is ⅓ of the number of columns of the first vertical transfer units 1, the solid-state imaging device 50 in the normal mode transfers the signal charges in order starting from the column C, the column R, and the column L, from the first vertical transfer unit 1 to the horizontal transfer unit 2 via the transfer control unit 6 and the second vertical transfer unit 9, and then transfers the signal charges from the horizontal transfer unit 2 to an output amplifier.

Moreover, in the embodiment 1 of the present invention, the case is shown where the number of drive phases of the first vertical transfer units 1 is 12. In this case, in the horizontal transfer period, the signal charges are stored by eight of the first vertical transfer electrodes 4. Moreover, in FIG. 3, the signal charges are stored by electrodes having applied thereto φV3 to φV10. During a horizontal blanking period shown in FIG. 3, three horizontal transfer electrodes 14 (φH1, φH2, φH3) among four horizontal transfer electrodes 14 are brought to a high level (for example, 1.8 V). The number of drive phases of the first vertical transfer units 1 may be other than 12. For example, the number of drive phases of the first vertical transfer units 1 may be 6, 8, or the like.

First, the solid-state imaging device 50 transfers the signal charges to the signal charge storage electrode 7 on each column. Specifically, at a time t0 shown in FIG. 3, the solid-state imaging device 50 brings φV11, which is applied to the first vertical transfer electrodes 4 adjacent to the transfer control unit 6, to a low level and also brings φVST-L, φVST-C, and φVST-R, which are applied to the signal charge storage electrodes 7, to a middle level (for example, 0 V) to transfer the signal charges to the signal charge storage electrodes 7 (FIG. 2A). Moreover, the solid-state imaging device 50 brings φVHLD-L, φVHLD-C, and φVHLD-R, which are applied to the transfer blocking electrodes 8 on respective columns, to a low level to form a potential barrier and thus prevents the signal charges from transferring to the next step.

Next, during a period from a time t1 to a time t2, the solid-state imaging device 50 maintains, at the low level, φVHLD-L and φVHLD-R, which are applied to the transfer blocking electrodes 8 on the columns L and R, respectively, and thereby the signal charges are retained by the signal charge storage electrodes 7. Moreover, the solid-state imaging device 50 transitions φVHLD-C, φVL2, and φVL, which are applied to the transfer blocking electrode 8 on the column C, the fourth vertical transfer electrode 12, and the vertical final electrode 13, respectively, to the middle level or a high level. Accordingly, the solid-state imaging device 50 transfers the signal charges on the column C to the horizontal transfer unit 2 (FIG. 2B).

Then, the solid-state imaging device 50 transfers the signal charges in the horizontal transfer unit 2 to the output unit to output the signal charges on the column C. In FIG. 3, the signal charge storage electrodes 7 are at the low level during the horizontal transfer period, but may not be at the low level.

Next, in a period from a time t3 to a time t4, the solid-state imaging device 50 maintains, at the low level, φVHLD-L which is applied to the transfer blocking electrode 8 on the column L to retain the signal charges on the column L by the signal charge storage electrode 7. Moreover, the solid-state imaging device 50 transitions φVHLD-R, φVL2, and φVL that are applied to the transfer blocking electrode 8 on the column R, the fourth vertical transfer electrode 12, and the vertical final electrode 13, respectively, to the middle level or the high level. Accordingly, the solid-state imaging device 50 transfers the signal charges on the column R to the horizontal transfer unit 2 (FIG. 2C). Then, the solid-state imaging device 50 transfers the signal charges on the horizontal transfer unit 2 to output the signal charges on the column R.

Subsequently, in a period from a time t5 to a time t6, the solid-state imaging device 50 transitions φVHLD-L, φVL2, and φVL that are applied to the transfer blocking electrode 8 on the column L, the fourth vertical transfer electrode 12, and the vertical final electrode 13, respectively, to the middle level or the high level to transfer the signal charges on the column L to the horizontal transfer unit 2 (FIG. 2D). Then, the solid-state imaging device 50 transfers the signal charges on the horizontal transfer unit 2 to output the signal charges on the column R.

The above-described operation allows a line of the signal charges to be outputted and the remaining signal charges to be sequentially outputted by the same operation.

Next, an operation of the solid-state imaging device 50 in a video mode will be described.

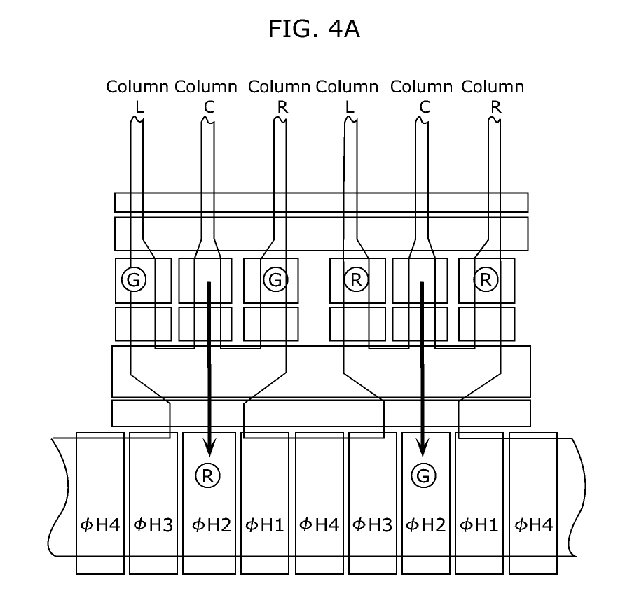

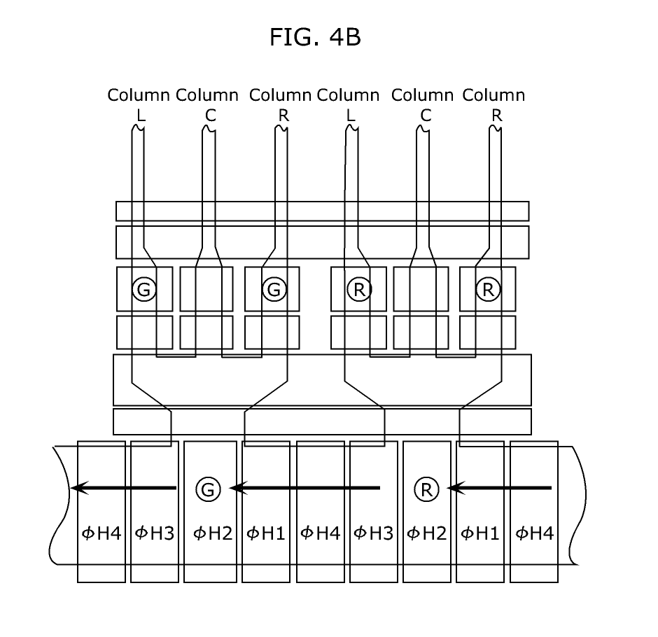

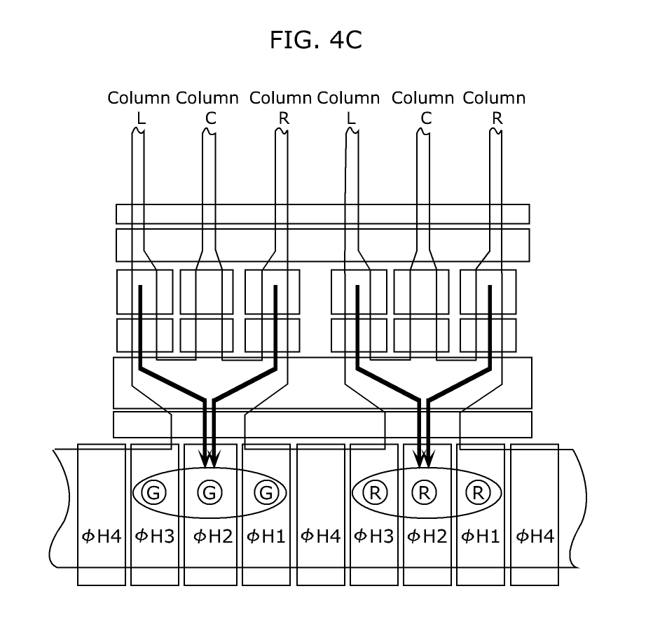

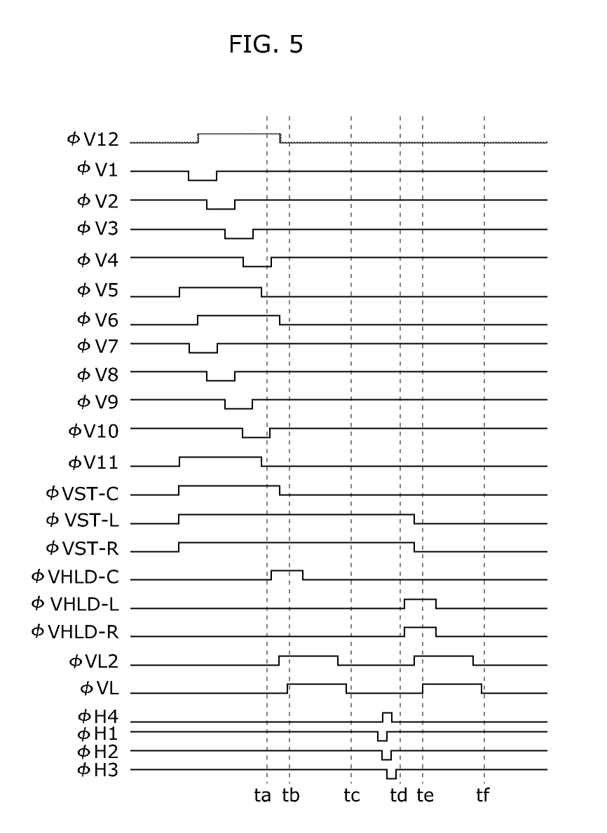

FIG. 4A to FIG. 4C are diagrams showing transfer of the signal charges by the solid-state imaging device 50 in the video mode. Moreover, FIG. 5 is a timing diagram showing drive timing in the video mode.

The solid-state imaging device 50 in the video mode performs a 3-pixel summing on the signal charges which are adjacent to one another in the horizontal direction and have a same color. Similarly to the normal mode, in a horizontal blanking period shown in FIG. 5, three horizontal transfer electrodes 14 (φH1, φH2, and φH3) among four horizontal transfer electrodes 14 are brought to a high level (for example, 1.8 V).

First, as indicated at a time to in FIG. 5, similarly to the operation in the normal mode, the solid-state imaging device 50 brings φV11, which is applied to the first vertical transfer electrodes 4 adjacent to the transfer control unit 6, to a low level, and φVST-L, φVST-C, and φVST-R, which are applied to the signal charge storage electrode 7, to a middle level or a high level, to transfer the signal charges on respective columns to the signal charge storage electrodes 7 (FIG. 2A). Moreover, the solid-state imaging device 50 brings φVHLD-L, φVHLD-C, and φVHLD-R, which are applied to the transfer blocking electrodes 8 on respective columns, to the low level to form the potential barrier and thus prevents the signal charges from transferring to the next step.

Next, in a period from a time tb to a time tc, the solid-state imaging device 50 maintains, at the low level, φVHLD-L and φVHLD-R which are applied to the transfer blocking electrodes 8 on the columns L and R, respectively, and thereby the signal charges are retained by the signal charge storage electrode 7. Moreover, the solid-state imaging device 50 transitions φVHLD-C, φVL2, and φVL, which are applied to the transfer blocking electrode 8 on the column C, the fourth vertical transfer electrode 12, and the vertical final electrode 13, respectively, to the middle level or the high level. Accordingly, the solid-state imaging device 50 transfers the signal charges on the column C to the horizontal transfer unit 2 (FIG. 4A).

Then, in a period from a time tc to a time td, the solid-state imaging device 50 transfers the signal charges in the horizontal transfer unit 2 in the left direction by three columns (FIG. 4B).

Subsequently, in a period from a time te to a time tf, the solid-state imaging device 50 transitions φVHLD-L and φVHLD-R that are applied to the transfer blocking electrodes 8 on the columns L and R, respectively, φVL2 applied to the fourth vertical transfer electrode 12, and φVL applied to the vertical final electrode 13, to the middle level or the high level. Accordingly, the solid-state imaging device 50 transfers the signal charges on the columns L and R to the horizontal transfer unit 2, thereby summing the signal charges of three pixels (FIG. 4C).

Moreover, the solid-state imaging device 50 is provided with a plurality of readout electrodes in the first vertical transfer units 1, and performs the 3-pixel summing in the first vertical transfer units 1 by devising how to drive the plurality of readout electrodes. Thus, the solid-state imaging device 50 achieves the operation of a 9-pixel summing in combination with the aforementioned summing of the three horizontal pixels. The example is aforementioned in which, as the operation of summing the horizontal signals, the signal charges on the column C are first transferred and added together with the signal charges on the columns L and R in the horizontal transfer unit 2. However, the signal charges on the columns L and R can first be transferred and then added together with the signal charges on the column C in the horizontal transfer unit 2.

Moreover, the case is shown in FIG. 1 where the horizontal transfer unit 2 is of the four-phase drive. In this case, at least one of four horizontal transfer electrodes 14 may be used as a barrier. That is, as described above, FIG. 1 shows a layout in which three horizontal transfer electrodes 14 having being brought to the high level receive the signal charges from the fifth vertical transfer unit 11 in the horizontal blanking period. The solid-state imaging device 50 may receive the signal charges in two of the horizontal transfer electrodes 14 having being brought to the high level.

Moreover, in the case of the three-phase drive, the horizontal transfer unit 2 may receive the signal charges from the second vertical transfer unit 9 after one or two of three horizontal transfer electrodes 14 have been brought to the high level. Moreover, in the case of the two-phase drive, the horizontal transfer unit 2 may receive the signal charges after one of two horizontal transfer electrodes 14 has been brought to the high level. As described above, the number of horizontal transfer electrodes 14 that can be set to the high level and the width of the electrodes in the horizontal blanking period vary depending on the number of drive phases. However, the structure, in which the first vertical transfer units 1 are grouped at the second vertical transfer unit 9, can advantageously accommodate a plurality of drive methods having different numbers of phases, by changing the width of the fifth vertical transfer units 11 and the layout of the fourth vertical transfer unit 10.

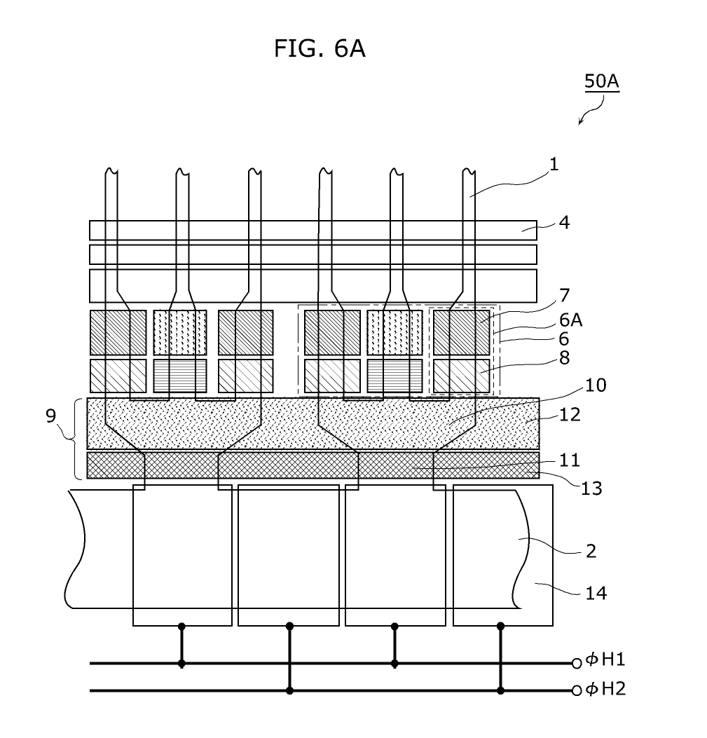

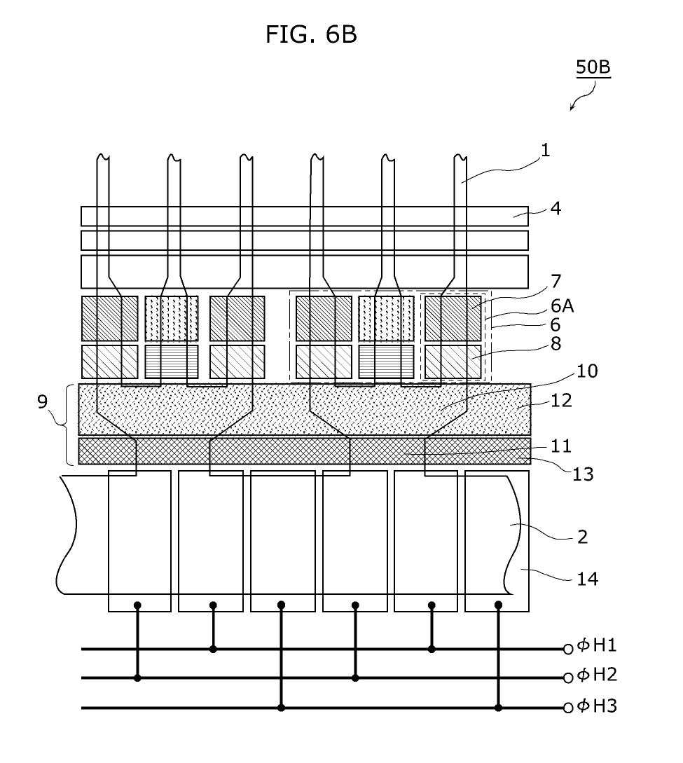

FIG. 6A is a diagram showing a configuration of a solid-state imaging device 50A corresponding to a horizontal two-phase drive. Moreover, FIG. 6B is a diagram showing a configuration of a solid-state imaging device 50B corresponding to the three-phase drive. The configurations of the transfer control unit 6 and the second vertical transfer unit 9 in FIG. 6A and FIG. 6B are the same as those shown in FIG. 1, and thus a wiring diagram of applied transfer pulses is omitted.

Operations of the first vertical transfer units 1, the transfer control unit 6, the second vertical transfer unit 9, and the horizontal transfer unit 2 are controlled by a drive unit not shown. That is, the aforementioned φV1 to φV12, φVST-C, φVST-L, φVST-R, φVHLD-C, φVHLD-L, φVHLD-R, φVL, φVL2, φH1 to φH4, and the like are generated by the drive unit. The drive unit may be included in the solid-state imaging device 50 or formed outside the solid-state imaging device 50.

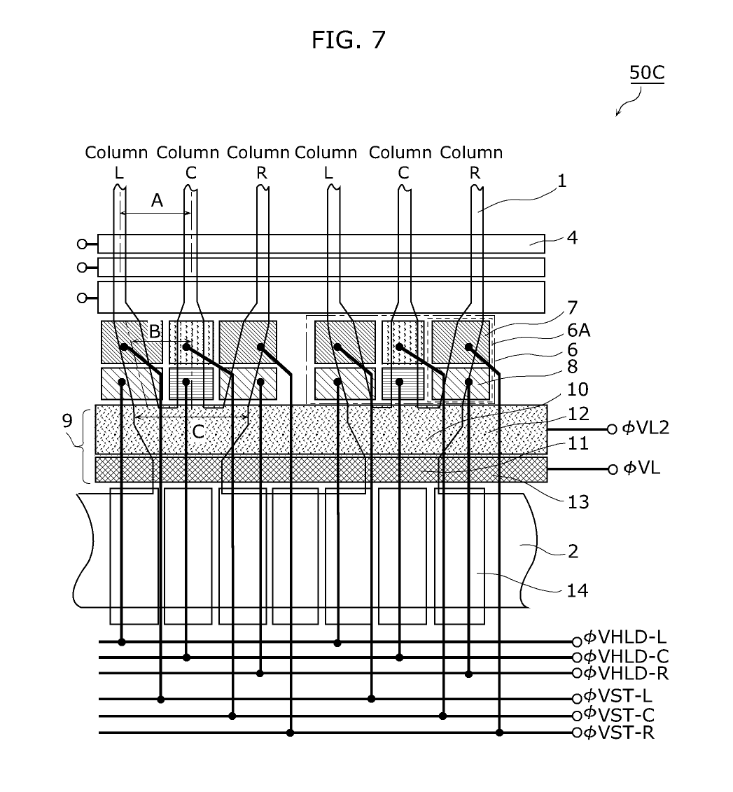

Moreover, as the second feature of the present embodiment, three columns of the third vertical transfer units 6A in the transfer control unit 6 are disposed so as to have shorter repetition pitches B therebetween than repetition pitches B between the first vertical transfer units 1 of the pixel repetition unit 5. However, the repetition pitches B are not limited by the third vertical transfer unit 6A being disposed perpendicular to the horizontal transfer unit 2 as shown in FIG. 1. As with the solid-state imaging device 50C shown in FIG. 7, the third vertical transfer unit 6A may be disposed along with oblique directions so as to be directed inwardly to the three columns that are toward the side of the second vertical transfer unit 9. In this case also, the relationship between the pitches A and B satisfies A>B.

Here, the repetition pitch B is a distance between the centers, at any position in the vertical transfer direction, of adjacent two third vertical transfer units 6A among three columns of the third vertical transfer units 6A.

The solid-state imaging device 50 according to the embodiment 1 of the present invention may include all or any one or more of the first to sixth features described above.

Next, reasons why the solid-state imaging device 50 can improve the degradations of transfer from a VOG unit (the second vertical transfer unit 9) grouping the plurality of first vertical transfer units 1 to the horizontal transfer unit 2 will be described for each of the first to sixth features, with reference to the accompanying drawings.

First, effects will be described which are obtained by incorporating a configuration which is the first feature in which the second vertical transfer unit 9 has a region where the transfer width reduces from the transfer control unit 6 toward the horizontal transfer unit 2.

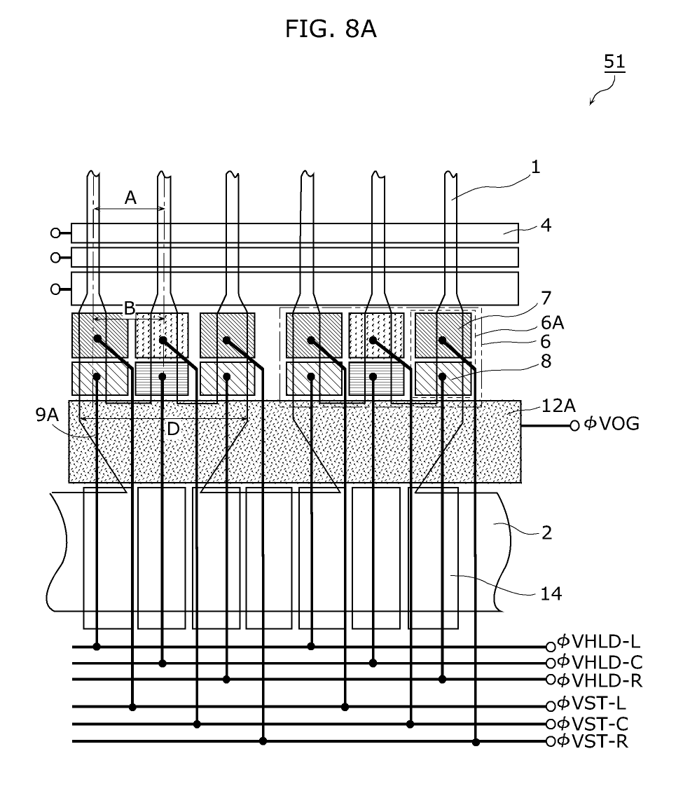

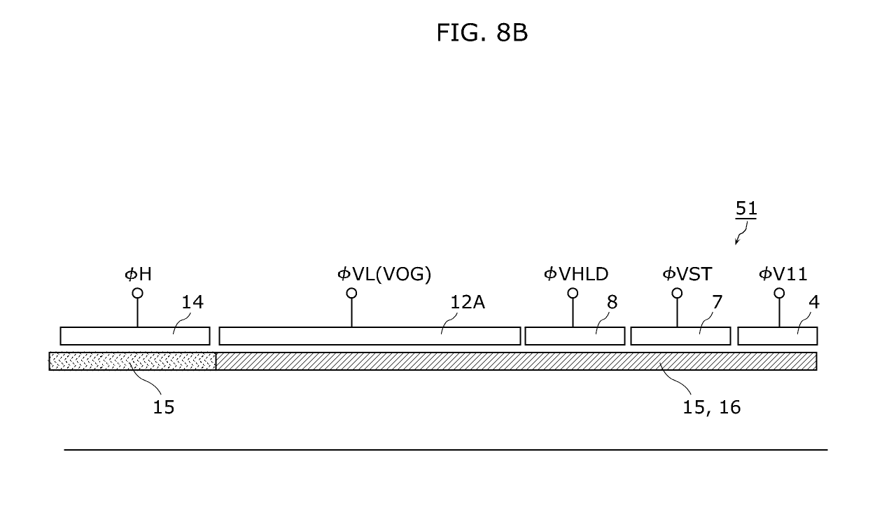

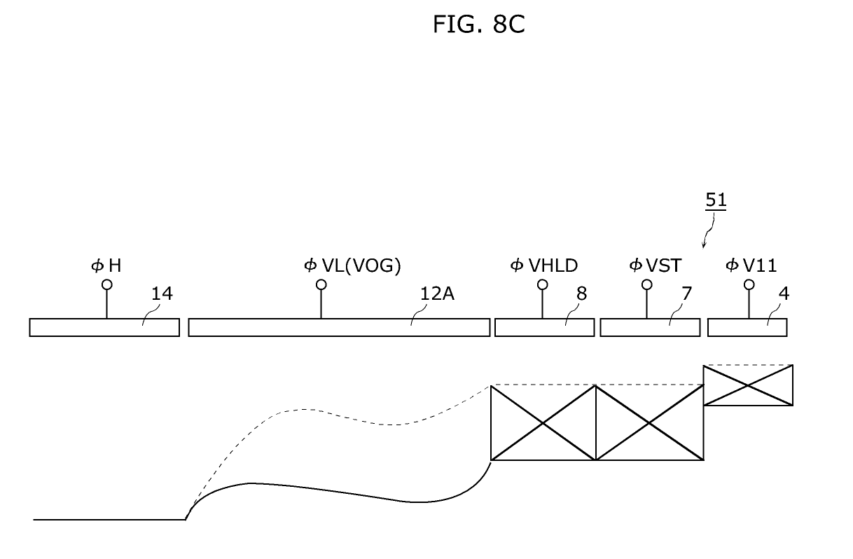

FIG. 8A is a top view of a solid-state imaging device 51 having the first feature. FIG. 8B is a sectional view showing a cross-sectional configuration of the solid-state imaging device 51. FIG. 8C is a diagram schematically illustrating potential distribution in the cross section.

The solid-state imaging device 51 does not have the second feature and the third feature. That is, the repetition pitches B between three columns of the third vertical transfer units 6A are the same as the repetition pitches between the first vertical transfer units 1. Moreover, the solid-state imaging device 51 includes a second vertical transfer unit 9A instead of the second vertical transfer unit 9. In addition, one second vertical transfer electrode 12A to which φVOG is applied is formed above the second vertical transfer unit 9.

The above configuration allows the solid-state imaging device 51 to have the horizontal transfer unit 2 gently tapering along with the transfer direction, and thus prevents the electric potential from being shallow on the side of the horizontal transfer unit 2. Thus, the solid-state imaging device 50 can prevent the occurrence of the transfer degradations.

Next, effects will be described which are obtained by incorporating a configuration set forth as the second feature in which three columns of the first vertical transfer units 1 in the transfer control unit 6 are disposed so as to have shorter repetition pitches therebetween than repetition pitches between the first vertical transfer units 1 of the pixels repetition unit 5.

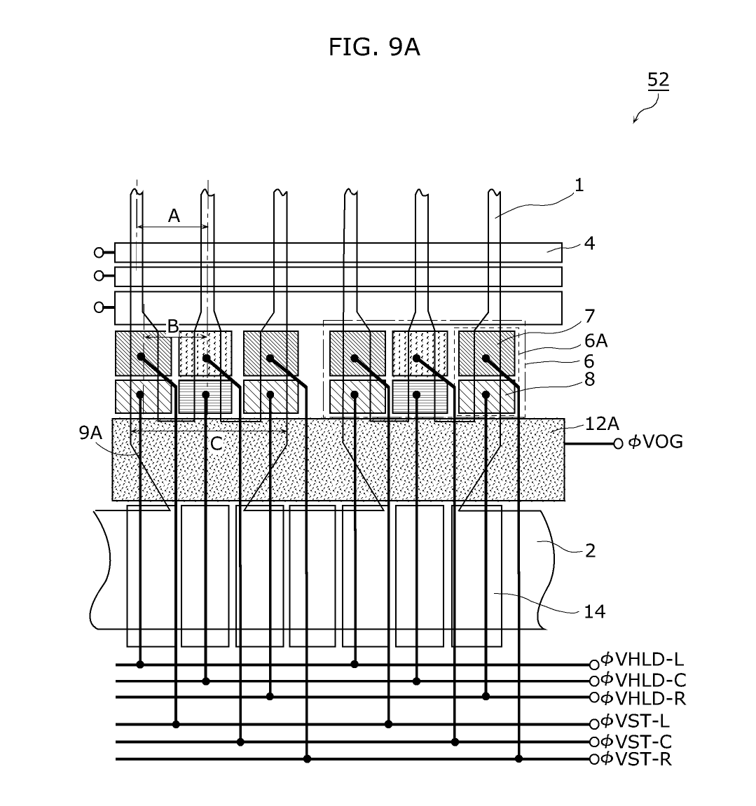

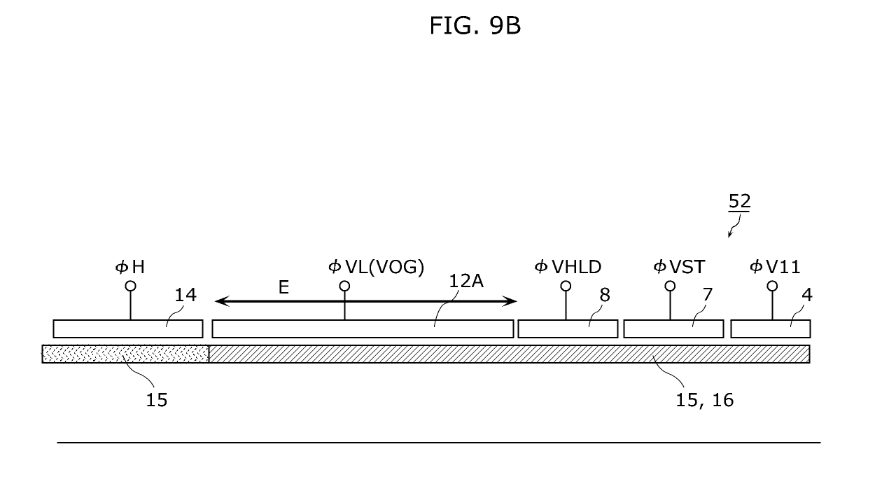

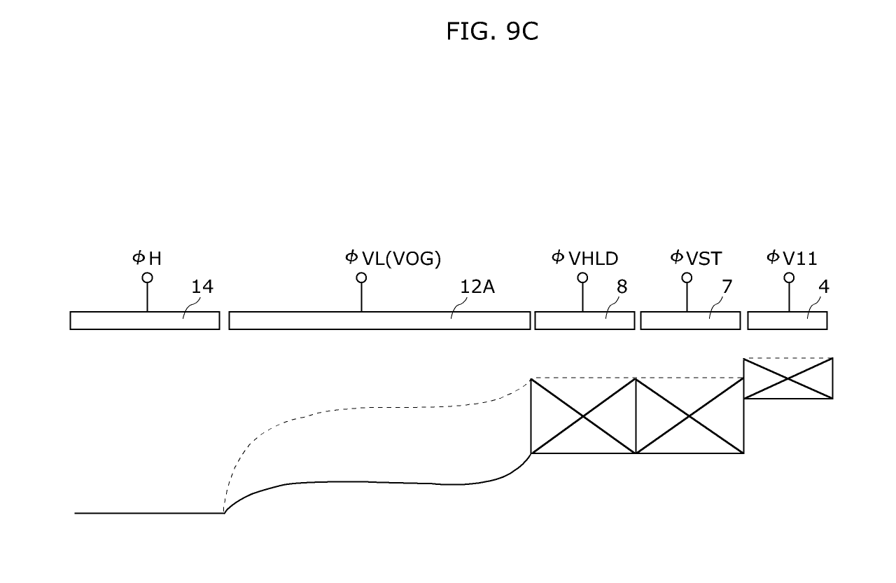

FIG. 9A is a top view of a solid-state imaging device 52 having the second feature. FIG. 9B is a sectional view showing a cross-sectional configuration of the solid-state imaging device 52. FIG. 9C is a diagram schematically illustrating potential distribution in the cross section. In FIG. 8C and FIG. 9C, a dotted line indicates potential when a low level voltage is applied to each electrode and a solid line indicates potential when a middle level voltage (for example, 0 V) is applied to each electrode.

First, the potential distribution when the signal charges are transferred from the second vertical transfer unit 9A to the horizontal transfer unit 2 in the solid-state imaging device 51 shown in FIG. 8B and FIG. 8C will be described.

The second vertical transfer unit 9A has a transfer width tapering along with the transfer direction, and thus the electric potential becomes shallower near the horizontal transfer unit 2. Moreover, in the case where the second vertical transfer unit 9A includes a first n-type impurities-doped region 15 and a second n-type impurities-doped region 16 as with the pixel repetition unit 5, the electric potential at application of a middle level voltage (for example, 0 V) is very deep. This reduces a difference in potential between the horizontal transfer unit 2 when a high level voltage is applied to the horizontal transfer electrodes 14 and the second vertical transfer unit 9A when a low level voltage is applied to the second vertical transfer unit 9A.

Because of this, a potential barrier is present as indicated by the dotted line in FIG. 8C even if the low level voltage is applied to the second vertical transfer unit 9A, causing bad transfer to occur. In addition, to ensure the transfer electric field between an outlet portion and an FD (floating diffusion) unit of the horizontal transfer unit 2, limitation is placed that the electric potential of the horizontal transfer unit 2 cannot be established deep.

In contrast, in the solid-state imaging device 52 which has the second feature as shown in FIG. 9A, the width in the horizontal direction in the second vertical transfer unit 9 is reduced to a width C indicated in FIG. 9A from a width D indicated in FIG. 8A.

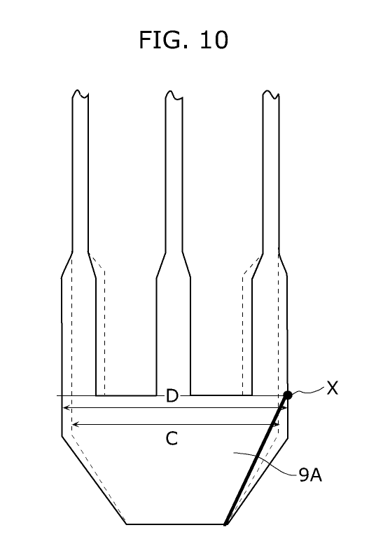

FIG. 10 is a top view showing the vicinity of the second vertical transfer units 9A of the solid-state imaging devices 51 and 52. A solid line shown in FIG. 10 depicts the second vertical transfer unit 9A of the solid-state imaging device 51 and a dotted line depicts the second vertical transfer unit 9A of the solid-state imaging device 52. Moreover, a cross-sectional configuration of the solid-state imaging device 52 shown in FIG. 9B is the same as the cross-sectional configuration of the solid-state imaging device 51 shown in FIG. 8B.

As shown in FIG. 10, the width C, in the horizontal direction, of the second vertical transfer unit 9A of the solid-state imaging device 52 on the side of the transfer control unit 6 is shorter than the width D in the solid-state imaging device 51 because the repetition pitches B between the third vertical transfer units 6A are shorter than the repetition pitches A between the first vertical transfer units 1. Thus, as compared to the solid-state imaging device 51, the solid-state imaging device 52 is required to have a less amount of reduction in width of the second vertical transfer unit 9A toward the horizontal transfer unit 2. This causes the solid-state imaging device 52 to have a potential shallower toward the horizontal transfer unit 2. However, the degree of shallowness remains slight, and thus the transfer efficiency can improve.

In FIG. 10, the second vertical transfer units 9A in the solid-state imaging devices 51 and 52 each include a region having a constant width and a region the width of which decreases toward the side of the horizontal transfer unit 2. However, the second vertical transfer unit 9A may include solely the region the width of which decreases toward the side of the horizontal transfer unit 2.

Even in the case described above where the width of the second vertical transfer unit 9A tapers starting from points X (thick line) at a boundary between the third vertical transfer unit 6A and the second vertical transfer unit 9A at left and right end portions thereof, by having the second feature, an angle of tapering is similarly gentle and also the electric potential gradient is reduced. In this case, however, the electric potential near the points X of the second vertical transfer unit 9A reduces due to the effect of the surrounding P-type region. Thus, there is a concern that the transfer efficiency from the transfer blocking electrode 8 to the second vertical transfer unit 9A may be worsen. Preferably, the second vertical transfer unit 9A has a region that has a constant width on the side of the transfer control unit 6 so that the electric potential does not thus decrease.

Next, effects will be described which are the third feature and obtained by providing the fourth vertical transfer unit 10 and the fifth vertical transfer unit 11 with the fourth vertical transfer electrode 12 and the vertical final electrode 13, respectively, as independent electrodes.

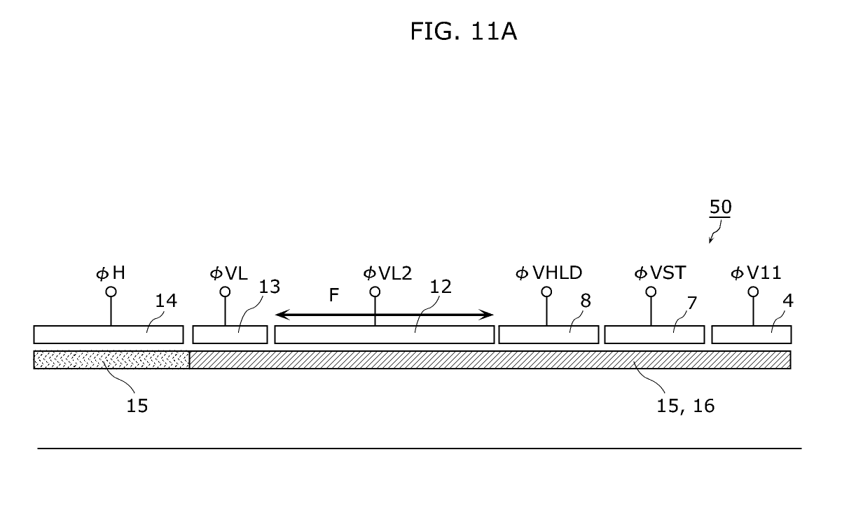

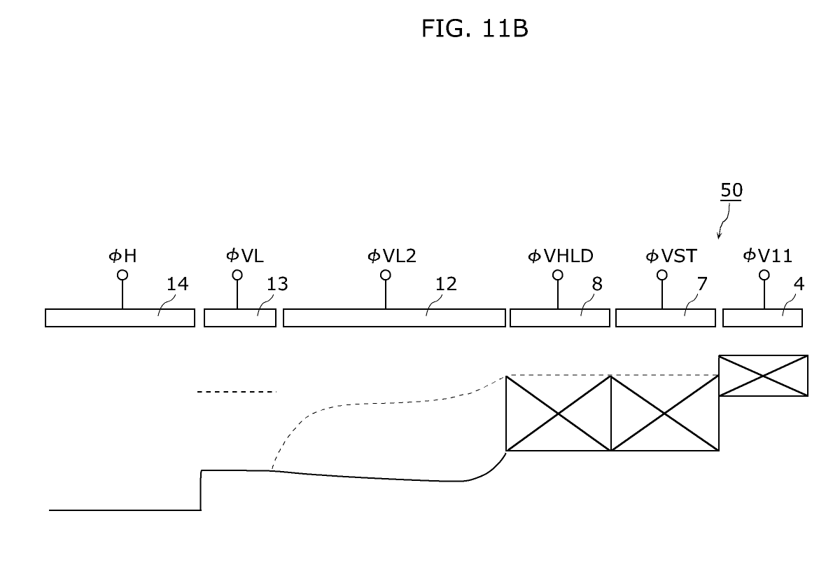

FIG. 11A is a diagram showing a cross-sectional configuration of the solid-state imaging device 50 incorporating the third feature. FIG. 11B is a diagram schematically illustrating the potential distribution in the cross section. The top view of the solid-state imaging device 50 is shown in FIG. 1.

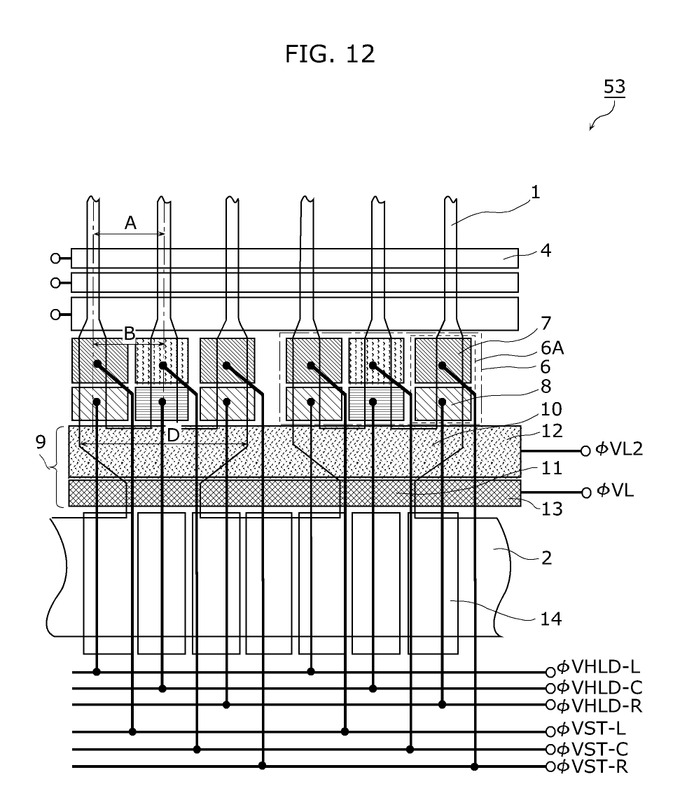

FIG. 12 is a top view of the solid-state imaging device 53 that has the third feature and does not have the second feature (the repetition pitches B between three columns of the third vertical transfer units 6A are the same as the repetition pitches between the first vertical transfer units 1).

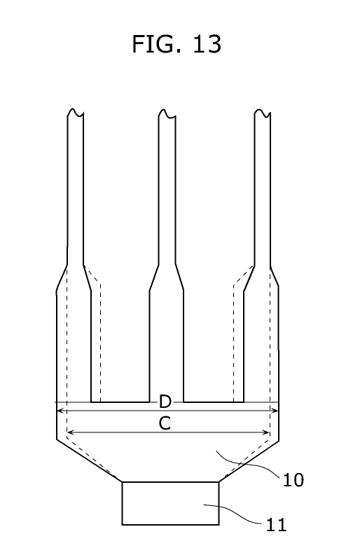

Moreover, FIG. 13 is a top view showing the vicinity of the second vertical transfer units 9 of the solid-state imaging device 53 shown in FIG. 12 and the solid-state imaging device 50 shown in FIG. 1. A solid line shown FIG. 13 depicts the second vertical transfer unit 9 of the solid-state imaging device 53 and a dotted line depicts the second vertical transfer unit 9 of the solid-state imaging device 50.

As shown in FIG. 13, the case having the third feature does not eliminate the advantages obtained from the second feature.

Here, in the solid-state imaging device 52 shown in FIG. 9A, the transfer efficiency is improved, but a fringing field may not sufficiently be obtained due to a long transfer length of the second vertical transfer unit 9A. In particular, in the case of recently available solid-state imaging devices in which pixel cells are miniaturized, the vertical transfer units are formed shallow to increase the handling quantity of electric charges and improve the smear characteristics. This deteriorates the transfer efficiency if the second vertical transfer unit 9A has a long transfer length.

Therefore, the fourth vertical transfer electrode 12 and the vertical final electrode 13 are formed above the second vertical transfer unit 9 shown in FIG. 1. Dividing the second vertical transfer unit 9 into the fourth vertical transfer unit 10 and the fifth vertical transfer unit 11 in this manner can shorten the length of the fourth vertical transfer unit 10. This allows the solid-state imaging device 50 to improve the transfer efficiency. That is, relationship E>F is satisfied in FIG. 9B and FIG. 11A.

Moreover, as shown in FIG. 11B, a potential difference when a middle level voltage and a low level voltage are applied to the vertical final electrode 13 and the fourth vertical transfer electrode 12, respectively, reduces as compared to the case shown in FIG. 9C. However, a minimum electric field of the fourth vertical transfer unit 10 is determined depending on the electrode length, and thus the overall transfer efficiency improves.

Next, effects will be described which are the fourth feature and obtained by forming a potential step in the fourth vertical transfer unit 10.

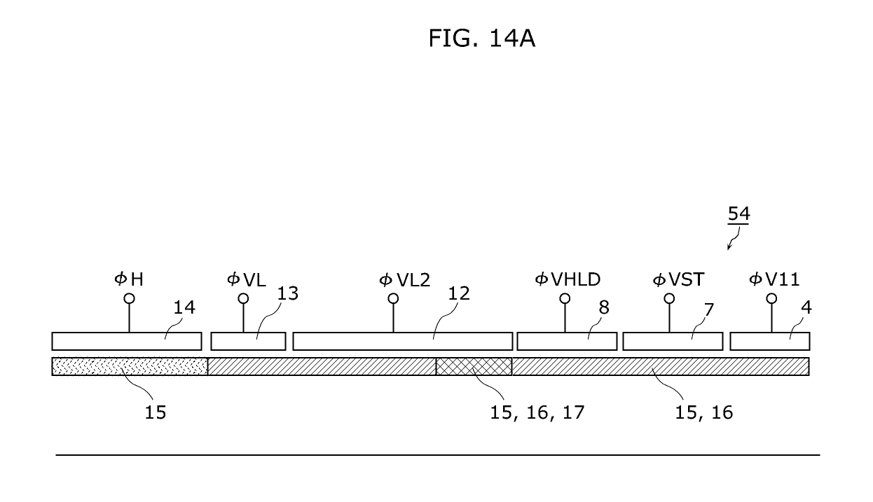

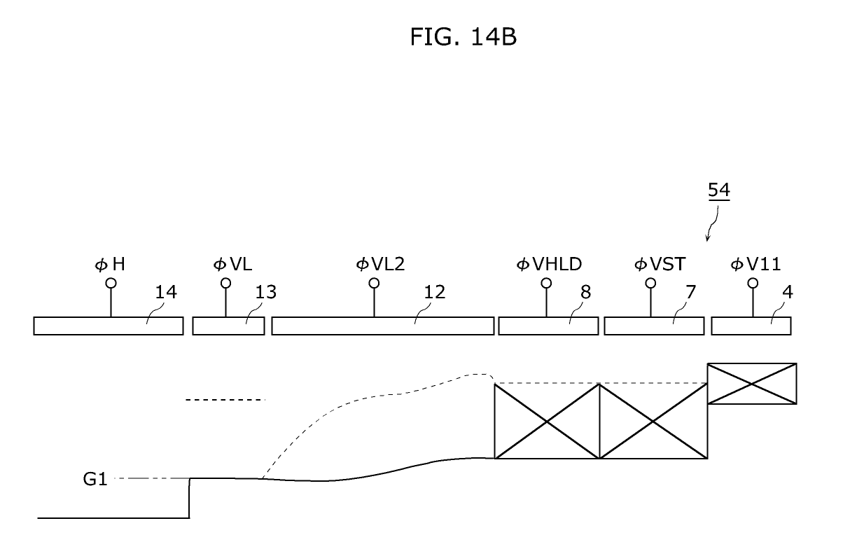

FIG. 14A is a diagram showing a cross-sectional configuration of a solid-state imaging device 54 incorporating the fourth feature. FIG. 14B is a diagram schematically illustrating the potential distribution in the cross section.

As shown in FIG. 14A, in the solid-state imaging device 54, a first p-type impurities-doped region 17 is formed to form the potential step such that the electric potential is shallow on the side of the transfer control unit 6 of the fourth vertical transfer unit 10. This allows creation of potential gradient in the transfer direction even if the transfer width tapers along with the transfer direction. Thus, the solid-state imaging device 54 allows further improvement of the transfer efficiency of the fourth vertical transfer unit 10.

Next, effects will be described which are a fifth feature and obtained by providing an impurities-doped region such that the second vertical transfer unit 9 has lower n-type impurity concentration than the first n-type impurities-doped region 15 and the second n-type impurities-doped region 16 which are included in the pixel repetition unit 5 and the transfer control unit 6, respectively.

Specifically, to suppress the reduction in handling quantity of electric charges and the transfer efficiency degradation due to the narrow channel effects in the pixel repetition unit 5, and also to ensure necessary handling quantity of electric charges using one electrode in the transfer control unit 6, for example, two n-type diffusion layers (the first n-type impurities-doped region 15 and the second n-type impurities-doped region 16) are used to form the first vertical transfer unit 1 and the third vertical transfer unit 6A. Moreover, for the n-type diffusion layer of the second vertical transfer unit 9, among the diffusion layers used to form the pixel repetition unit 5, a layer (the first n-type impurities-doped region 15) that is shared with the horizontal transfer unit 2 is used.

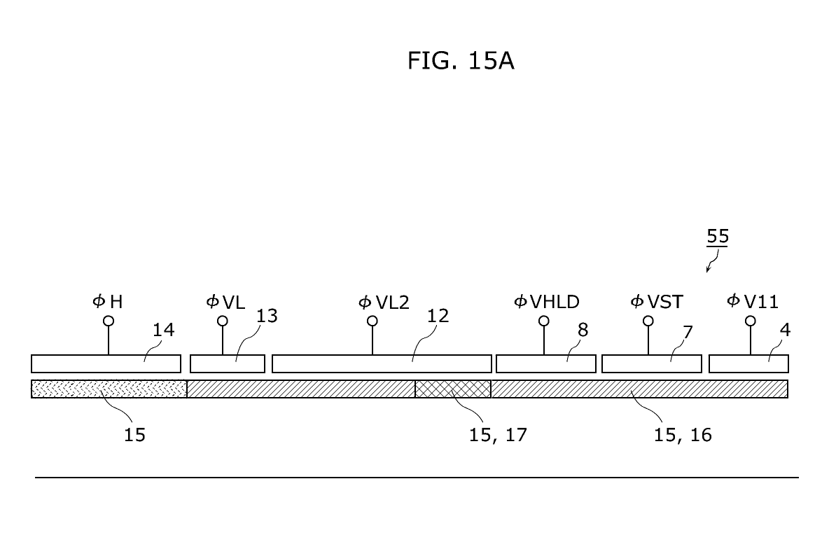

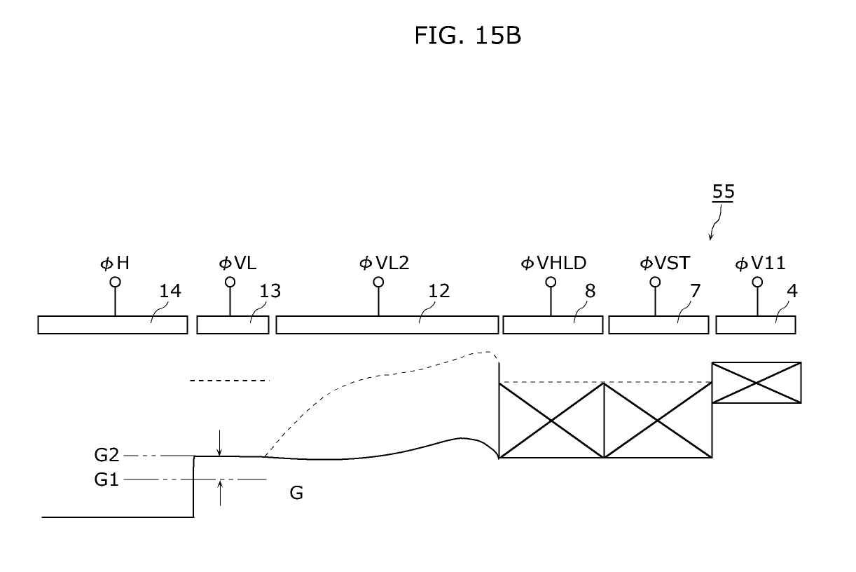

FIG. 15A is a diagram showing a cross-sectional configuration of a solid-state imaging device 55 incorporating the fifth feature. As shown in FIG. 15A, the solid-state imaging device 55 forms the second vertical transfer unit 9 using the first n-type impurities-doped region 15. That is, the first vertical transfer unit 1 includes the first n-type impurities-doped region 15 and the second n-type impurities-doped region 16. Moreover, the first n-type impurities-doped region 15 is formed in the first vertical transfer units 1, the transfer control unit 6, the second vertical transfer unit 9, and the horizontal transfer unit 2. Moreover, the second n-type impurities-doped region 16 is formed in the first vertical transfer units 1 and the transfer control unit 6, and is not formed in the second vertical transfer unit 9 and the horizontal transfer unit 2.

FIG. 15B is a diagram schematically illustrating the potential distribution in the cross section.

The solid-state imaging device 55 can form a shallow electric potential of the second vertical transfer unit 9 as shown in FIG. 15B, as compared to the case where the second vertical transfer unit 9 is formed using a same n-type impurity concentration as the pixel repetition unit 5 as in the solid-state imaging device 54 shown in FIG. 14B. This allows the solid-state imaging device 55 to establish a potential difference from the fifth vertical transfer unit 11 to the horizontal transfer unit 2 to be large by an amount indicated by G (G2-G1), as compared to the solid-state imaging device 54. This allows the solid-state imaging device 55 to greatly improve the transfer efficiency from the vertical final electrode 13 to the horizontal transfer unit 2.

Next, effects obtained by incorporating a sixth feature of the present embodiment will be described.

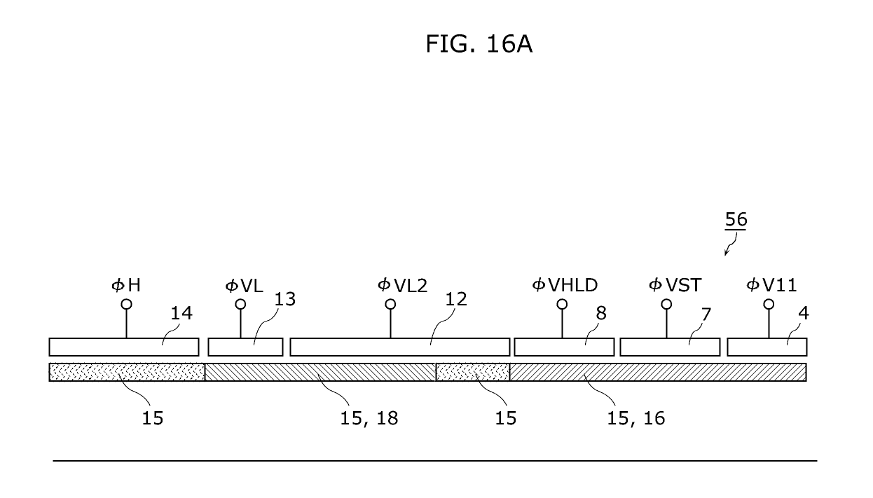

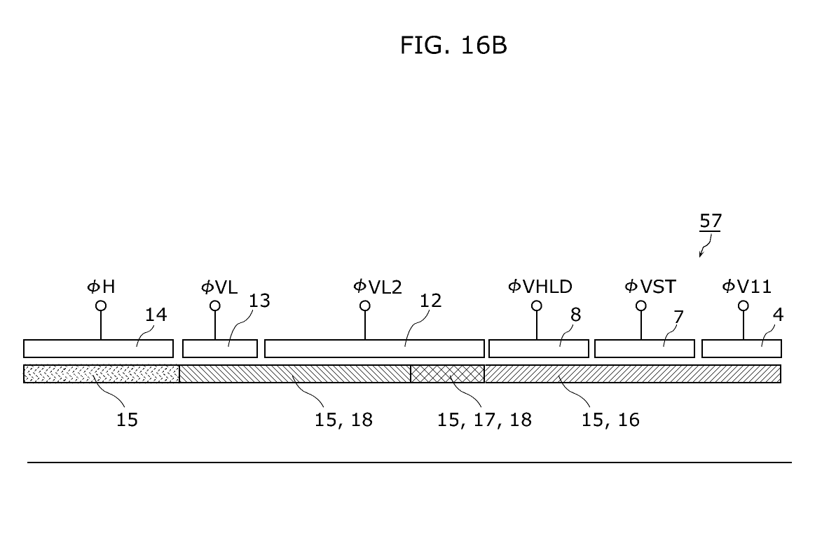

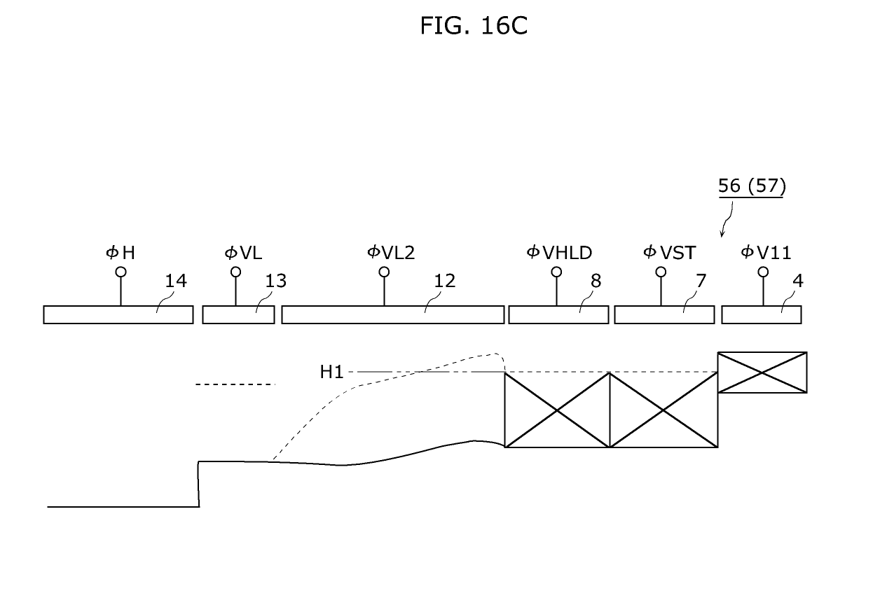

FIG. 16A and FIG. 16B are diagrams showing cross-sectional configurations of solid-state imaging devices 56 and 106, respectively, incorporating the sixth feature.

A first example of the sixth feature of the present embodiment is that a third n-type impurities-doped region 18 as shown in FIG. 16A and FIG. 16B is formed in the second vertical transfer unit 9.

In the solid-state imaging device 56 shown in FIG. 16A, the third n-type impurities-doped region 18 is formed in the second vertical transfer unit 9 (in the fifth vertical transfer unit 11 and the fourth vertical transfer unit 10 on the side of the horizontal transfer unit 2) on the side of the horizontal transfer unit 2 to form the potential step in the fourth vertical transfer unit 10 such that the electric potential on the side of the transfer control unit 6 is shallow. Accordingly, the solid-state imaging device 56 also has the fourth feature.

Moreover, as another example, in a solid-state imaging device 57 shown in FIG. 16B, the first n-type impurities-doped region 15 and the third n-type impurities-doped region 18 are formed in the second vertical transfer unit 9, and to form the potential step, the first p-type impurities-doped region 17 is formed in the fourth vertical transfer unit 10 on the side of the transfer control unit 6.

Moreover, FIG. 16C is a diagram schematically illustrating the potential distribution corresponding to the configurations shown in FIG. 16A and FIG. 16B.

Here, in the solid-state imaging device 55 incorporating the fifth feature which is shown in FIG. 15A and FIG. 15B, the formation of the potential step in the fourth vertical transfer unit 10 reduces the n-type impurity concentration of the second vertical transfer unit 9 to be smaller than the n-type impurity concentration of the first vertical transfer units 1 and the transfer control unit 6. That is, in the solid-state imaging device 55, forming the potential step using the first p-type impurities-doped region 17 reduces the concentration in the n-type impurities-doped region at which the potential step is formed. This undesirably ends up reducing the potential difference between the transfer control unit 6 and the fourth vertical transfer unit 10 in the solid-state imaging device 55, introducing a concern that the transfer failure may occur between the transfer blocking electrode 8 and the fourth vertical transfer unit 10, depending on a forming condition.

In contrast, the solid-state imaging devices 56 and 57 are provided the third n-type impurities-doped region 18 in the second vertical transfer unit 9 to ensure a sufficient potential difference between the transfer blocking electrode 8 and the fourth vertical transfer unit 10, provided that concentration of the third n-type impurities-doped region 18 is set lower than the concentration of the second n-type impurities-doped region 16. Accordingly, the solid-state imaging devices 56 and 57 ensure a sufficient potential difference also at a boundary between the horizontal transfer unit 2 and the second vertical transfer unit 9.

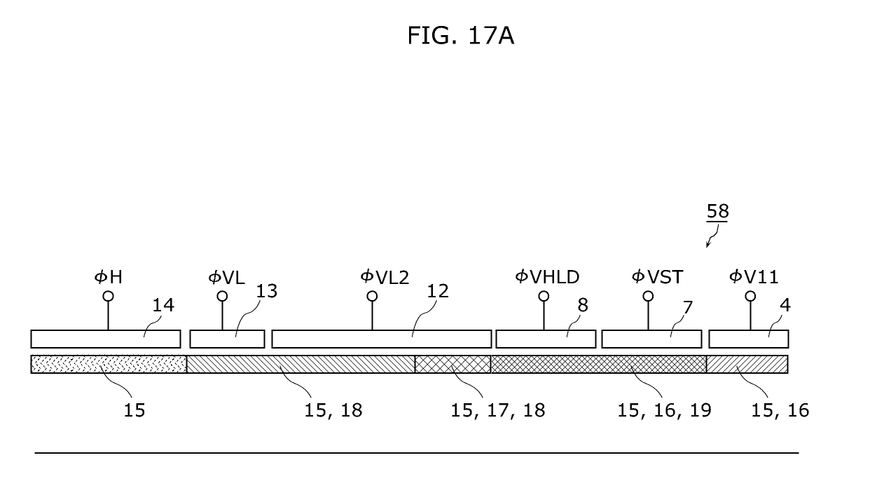

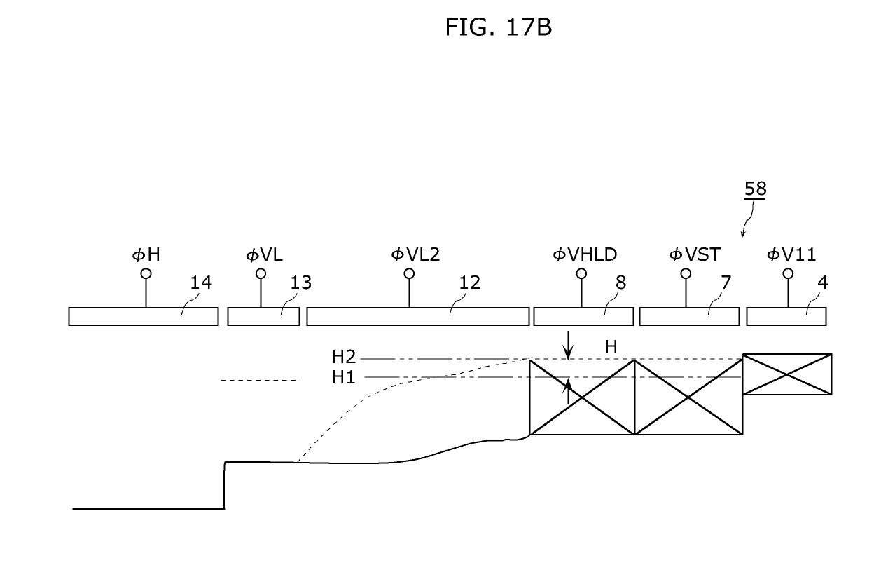

FIG. 17A shows another example of the cross-sectional configuration of the solid-state imaging device 58 incorporating the sixth feature. FIG. 17B is a diagram schematically illustrating the potential distribution in the cross section.

A second example of the sixth feature is that, as shown in FIG. 17A, a second p-type impurities-doped region 19 is formed in the third vertical transfer unit 6A (the transfer control unit 6) below the signal charge storage electrode 7 and the transfer blocking electrode 8.

This allows the solid-state imaging device 58 to establish the electric potential of the transfer control unit 6 to be shallow by an amount indicated by H (H2-H1) as shown in FIG. 17B, as compared to the case shown in FIG. 16C. Thus, the solid-state imaging device 58 can enhance the transfer electric field from the transfer control unit 6 to the fourth vertical transfer unit 10. Therefore, the improvement of the transfer efficiency is possible.

Moreover, the first vertical transfer units 1 have narrow widths and narrow electrode lengths as shown in FIG. 16C and the like and thus the electric potential of the signal charge storage electrodes 7 is deeper than the electric potential of the electrode under φV11. Therefore, even if the p-type impurities-doped regions are added below the signal charge storage electrodes 7, a problem does not occur in transfer as shown in FIG. 17B.

Moreover, the addition of the second p-type impurities-doped region 19 to establish a shallow electric potential of the transfer control unit 6 allows the solid-state imaging device 58 to establish a shallow electric potential below the second vertical transfer unit 9 as compared to the solid-state imaging devices 56 and 106. Thus, it is possible for the solid-state imaging device 58 to establish a large potential difference between a position below the vertical final electrode 13 and the horizontal transfer unit 2.

Here, the example is given in which the second p-type impurities-doped region 19 is further formed in addition to the configuration of the solid-state imaging device 57 shown in FIG. 16B. However, the second p-type impurities-doped region 19 may further be formed in addition to the configuration of any of the solid-state imaging devices 50 to 56 of the other examples described above.

Moreover, the n-type impurities-doped region and the p-type impurities-doped region are each a region formed by a single impurity implantation step. That is, forming a plurality of impurities-doped regions in a region (the first vertical transfer unit 1 or the like) is performing the impurity implantation on a region multiple number of times. Moreover, the types of the impurities and the impurities-implanted regions (the regions and the depths) in the multiple numbers of impurities implantations may be different or may be the same.

Moreover, as in the case of the embodiment 1 according to the present invention where the electrodes to which different transfer pulses are applied are disposed close to one another, if each electrode includes two layers, overlap between the electrodes impedes the wiring layout. Thus, preferably, the first vertical transfer electrodes 4, the signal charge storage electrodes 7, the transfer blocking electrodes 8, the fourth vertical transfer electrode 12, the vertical final electrode 13, and the horizontal transfer electrodes 14 are formed of a single layer.

As described above, according to the embodiment 1 of the present invention, in the configuration provided with the transfer control unit 6 which selectively controls transfer of the signal charges from the first vertical transfer unit 1 to the horizontal transfer unit 2, and the second vertical transfer unit 9, the solid-state imaging device can be achieved which allows the horizontal interlace achieving the suppression of the transfer degradations and the low power consumption and also allows the signal charge summing that is required in the video mode and the like.

### Embodiment 2

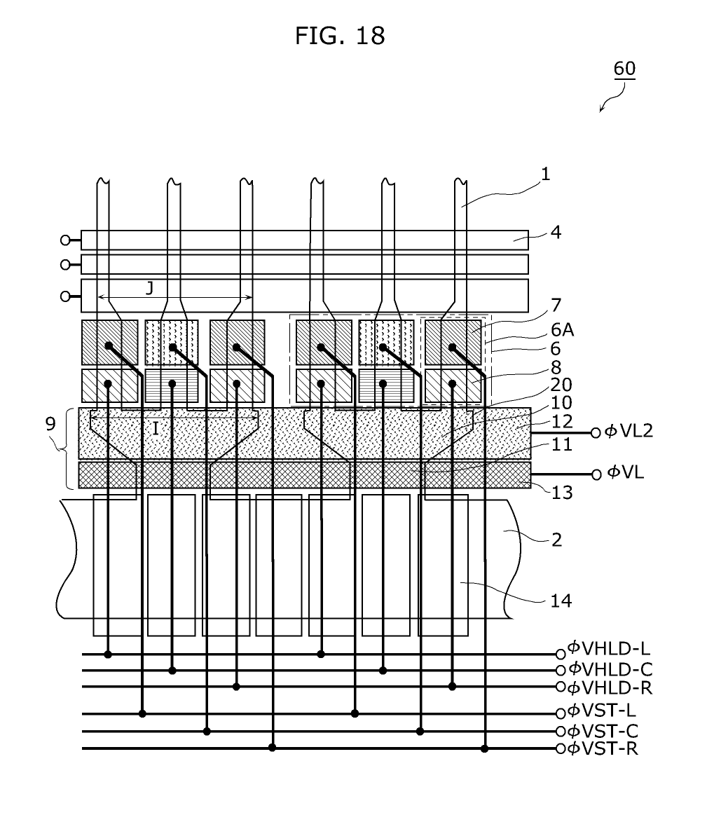

FIG. 18 is a diagram showing a configuration of a solid-state imaging device 60 according to an embodiment 2 of the present invention. The same reference signs are given to the same components as those shown in FIG. 1, and only a difference of the solid-state imaging device 60 from the solid-state imaging device 50 shown in FIG. 1 will be described below.

The solid-state imaging device 60 shown in FIG. 18 further includes a horizontal direction extension 20 in the fourth vertical transfer unit 10, in addition to the components included in the solid-state imaging device 50.

The horizontal direction extension 20 extends the width of the fourth vertical transfer unit 10 in the horizontal direction on a side adjacent to the transfer control unit 6. The horizontal direction extension 20 extends a width I of the fourth vertical transfer unit 10 in the horizontal direction on the side adjacent to the transfer control unit 6 so as to be larger than a total length J of three columns of the first vertical transfer units 1 (the third vertical transfer unit 6A) in the horizontal direction (I>J). That is, a maximum transfer width of the second vertical transfer unit 9 is larger than a width between outer end portions of the first vertical transfer units 1 positioned outermost among the three columns of the first vertical transfer units 1.

Here, at end portions of the fourth vertical transfer unit 10, the electric potential is shallow as compared to the vicinity of the central portion of the fourth vertical transfer unit 10 due to the effects of the surrounding p-type impurities. Thus, there is a problem that in transferring the signal charges from the transfer control unit 6 to the fourth vertical transfer unit 10, electric field decreases at the end portions as compared to the central portion.

On the other hand, the solid-state imaging device 60 allows the electric potential to be deep at the end portions as well as the central portion by using the above-described configuration. This allows the solid-state imaging device 60 to suppress bad transfer of the signal charges from the transfer control unit 6 to the fourth vertical transfer unit 10. The above-described configuration is effective in particular in the solid-state imaging devices 55, 56, and 57 that are shown in FIG. 15A, FIG. 15B, FIG. 16A, FIG. 16B, and FIG. 16C of the embodiment 1 where the electric potential of the transfer control unit 6 is deep.

In the solid-state imaging device 60, an amount of tapering of the fourth vertical transfer unit 10 toward the horizontal transfer unit 2 is large, but which does not cause any problem in transferring the signal charges insofar as the potential step is provided in the fourth vertical transfer unit 10 as shown in the embodiment 1.

Moreover, the example is given in which the solid-state imaging device 50 further includes the horizontal direction extension 20. However, the solid-state imaging devices 51 to 58 according to the embodiment 1 may further include the horizontal direction extension 20.

### Embodiment 3

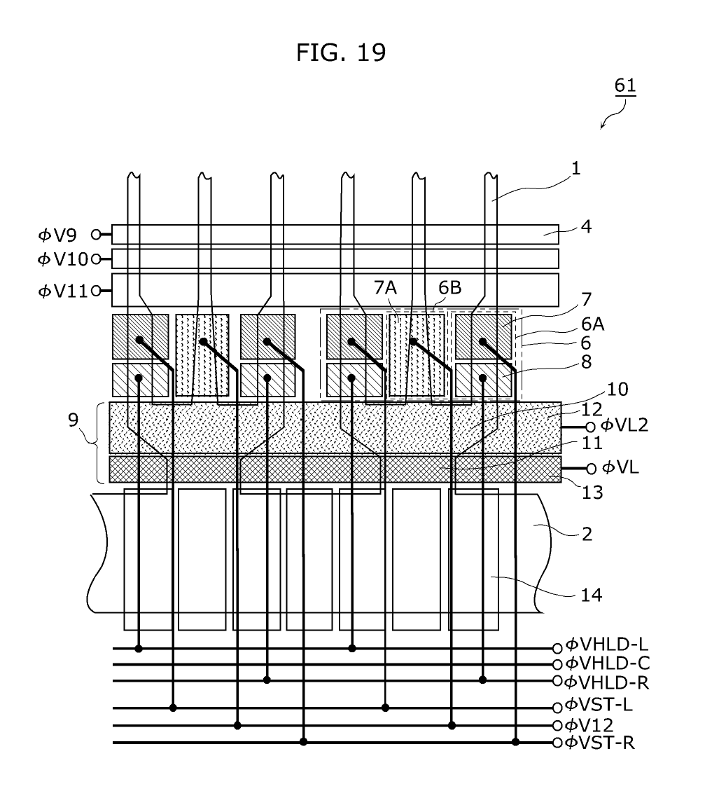

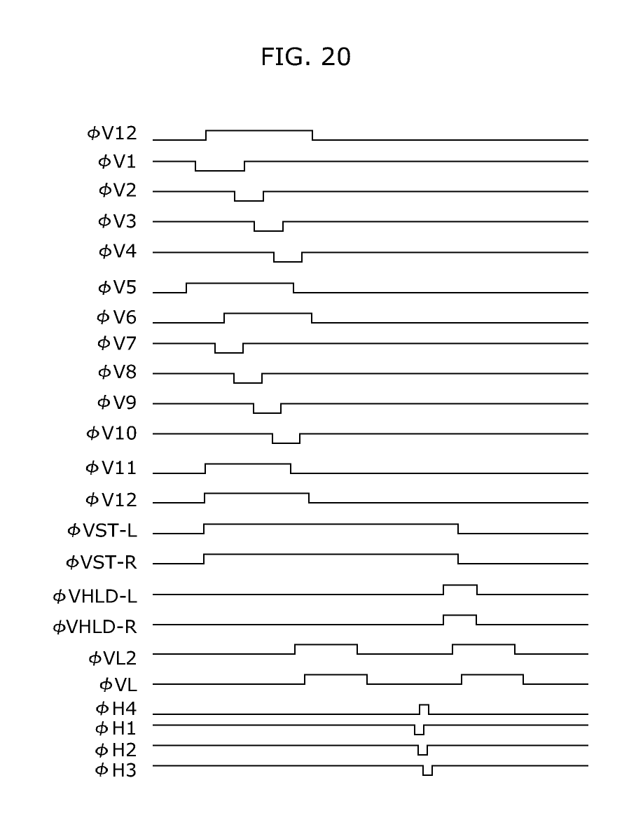

FIG. 19 is a diagram showing a configuration of a solid-state imaging device 61 according to an embodiment 3 of the present invention. FIG. 20 is a timing diagram showing drive timing of the solid-state imaging device 61 in the video mode. In FIG. 19, the reference signs same as those used in FIG. 1 refer to the same components. Moreover, the pixel repetition unit 5 is the same as that shown in FIG. 1 and thus omitted in FIG. 19.

In the embodiment 1, as with the columns R and L, the signal charge storage electrode 7 and the transfer blocking electrode 8 are disposed on the column C through which the signal charges are first transferred from the transfer control unit 6 to the horizontal transfer unit 2 in the normal mode and the video mode. However, on the column C through which the signal charges are first transferred, the signal charges are not necessarily retained. Thus, the same transfer pulse as the transfer pulse applied to the pixel repetition unit 5 can be applied to the electrodes of the transfer control unit 6 on the column C.

Specifically, in the normal mode, φVST-C and φV12 have the same drive timing as shown in FIG. 3, and thus φV12 can be applied to the electrodes to which φVST-C is applied.

In addition, the third vertical transfer unit 6A on the column C is not required to retain the signal charges and therefore may have a narrow width as compared to the third vertical transfer units 6A on the columns R and L.

Therefore, as in the embodiment 1 described above, the solid-state imaging device 61 shown in FIG. 19 includes the same third vertical transfer units 6A on the columns R and L and a third vertical transfer unit 6B on the column C.

The third vertical transfer unit 6B includes solely the third vertical transfer electrode 7A to which V12 is applied. Moreover, the entire region below the third vertical transfer electrode 7A of the third vertical transfer unit 6B has a transfer width increasing from the first vertical transfer unit 1 toward the second vertical transfer unit 9.

As described above, the solid-state imaging device 61 utilizes the narrow channel effects thereby improving the transfer electric field. This allows the solid-state imaging device 61 to include on the column C one sheet of the vertical transfer electrode that has the electrode length combining the lengths of two sheets of the electrodes on the columns L and R.

If the drive timing in the video mode that is shown in FIG. 20 is used in the configuration, the same summing operation as in the embodiment 1 can be achieved. In this case, the number of independent electrodes in the transfer control unit 6 can be reduced to four electrodes φVST-R, φVST-L, φVHLD-R, and φVHLD-L.

As described above, according to the embodiment 3 of the present invention, the solid-state imaging device 61 having a reduced number of independent electrodes in the transfer control unit 6 can be achieved.

In the configuration of the embodiment 3 according to the present invention, solely the third vertical transfer unit 6B is disposed on the column C. However, as shown in FIG. 2A to FIG. 2D, and FIG. 4A to FIG. 4C, the structure that includes solely the third vertical transfer unit 6B on the column L or R, instead of the column C, can be achieved by changing the order of the columns to be read out.

Moreover, the configuration of the embodiment 3 according to the present invention may be applied to the solid-state imaging devices 51 to 58 according to the embodiment 1 and the solid-state imaging device 60 according to the embodiment 2.

### Embodiment 4

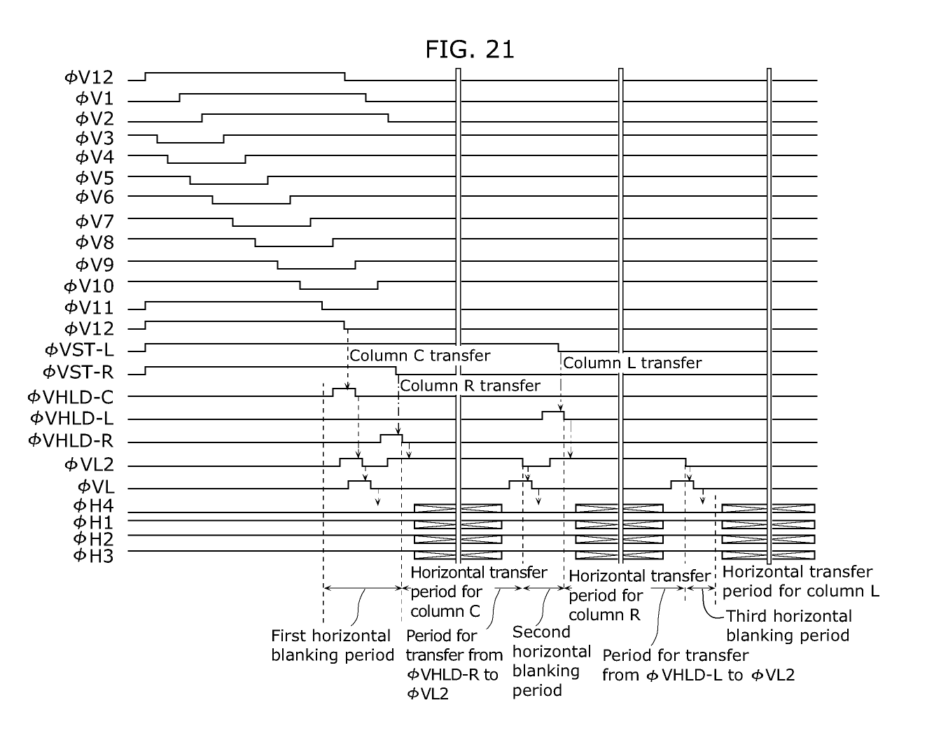

As described in the embodiment 1, if it is difficult to transfer the signal charges from the transfer control unit 6 to the second vertical transfer unit 9, the improvement of the transfer is possible by using a drive shown in FIG. 21.

In a horizontal transfer period for the signal charges on one of the three columns, a solid-state imaging device according to an embodiment 4 of the present invention transfers the signal charges on another column from the transfer control unit 6 to the fourth vertical transfer unit 10.

Here, the vicinity of the central portion of the fourth vertical transfer unit 10 has a deepest electric potential, and thus a potential difference between the third vertical transfer unit 6A and the fourth vertical transfer unit 10 on the column C is large. Therefore, large transfer electric fields of the third vertical transfer unit 6A and the fourth vertical transfer unit 10 on the column C can be ensured, and thus it is easier to transfer the signal charges on the column C than on outermost columns (the columns R and L).

Thus, for example, in the case of 3:1 interlace in which a line of signals is separated for every three signals and horizontally transferred, the signal charges on the center column C are transferred in a first horizontal blanking period, from the first vertical transfer unit 1 to the horizontal transfer unit 2 via the transfer control unit 6 and the second vertical transfer unit 9 as shown in FIG. 21. Then, the signal charges on the column R are transferred from the signal charge storage electrode 7 to the transfer blocking electrode 8. Moreover, the horizontal transfer period (a period for which the signals are outputted) for the center column C that has transferred the signal charges thereon is used to transfer the signal charges on the outermost column R from the transfer blocking electrode 8 to the fourth vertical transfer unit 10 over a long period of time. This allows improvement in transfer efficiency. In this case, the signals on the column R are transferred to the horizontal transfer unit 2 in the beginning of the second horizontal blanking period.

In the second horizontal blanking period, the signal charges on the column L are transferred from the signal charge storage electrode 7 to the transfer blocking electrode 8. Moreover, the horizontal transfer period for the column L is used to transfer the signal charges on the column L from the transfer blocking electrode 8 to the fourth vertical transfer unit 10. Moreover, signals on the column L are transferred to the horizontal transfer unit 2 in a third horizontal blanking period.

As described above, according to the embodiment 4 of the present invention, it is possible to transfer the signal charges in the third vertical transfer units 6A on the outermost columns on which the transfer failure is likely to occur, to the fourth vertical transfer unit 10 in the horizontal transfer period over a long period of time. Thus, the solid-state imaging device which suppresses the transfer failure can be achieved.

### Embodiment 5

The present invention is also applicable to the case where a plurality of the horizontal transfer units 2 is provided. In particular, to achieve a mode requiring a high-speed signal output among video modes, for example, a video output at 30 frames/second for pixels (1920×1080) used for full HD video, it is important to reduce the horizontal transfer frequency by providing the plurality of horizontal transfer units 2. This allows the low voltage drive of the horizontal transfer units 2 while suppressing the bad transfer, and this is advantageous in achieving low power consumption. Moreover, an increase of output signal frequency can be suppressed and thus the timing setting for sample-and-hold in CDS (correlated double sampling) can be facilitated. Moreover, the present invention supports commercially available AFE (Analog Front End) chips, which advantageously allow a set to be readily configured and low cost. Furthermore, the frame rate for outputting a still image which is the normal mode can be improved and thus dark currents present in the first vertical transfer units 1 can be suppressed. Thus, noise reduction is also possible.

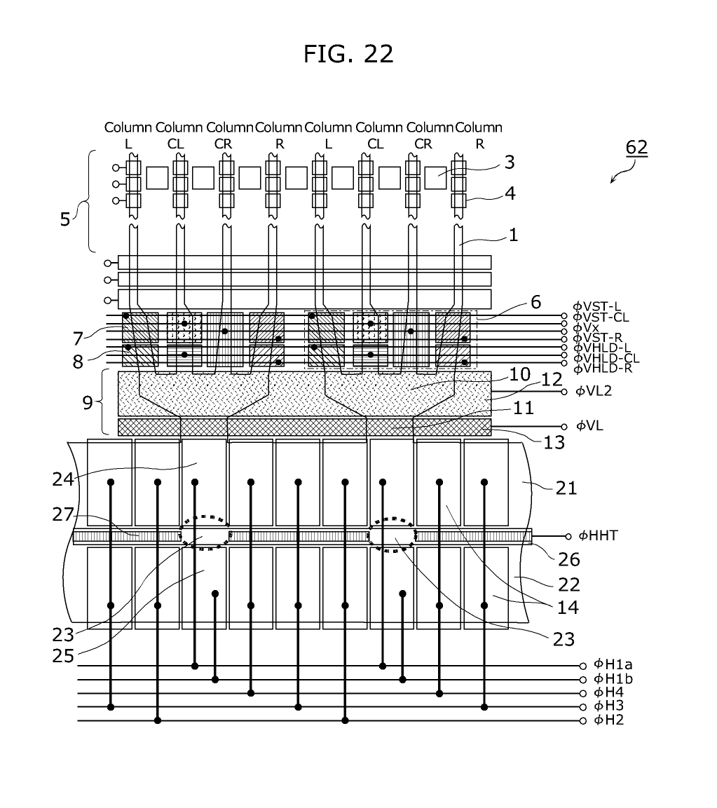

FIG. 22 is a diagram showing a configuration of a solid-state imaging device 62 according to an embodiment 5 of the present invention. The same reference signs are given to the same components as those shown in FIG. 1, and only a difference of the solid-state imaging device 62 from the solid-state imaging device 50 will be described below.

The solid-state imaging device 62 shown in FIG. 22 includes a first horizontal transfer unit 21, a second horizontal transfer unit 22, distribution transfer units 23, first horizontal transfer electrodes 24, second horizontal transfer electrodes 25, a distribution transfer electrode 26, and a channel stop region 27, instead of the horizontal transfer unit 2.

The first horizontal transfer unit 21 and the second horizontal transfer unit 22 are of the four-phase drive.

The first horizontal transfer electrode 24 and the second horizontal transfer electrode 25 are provided above and below the distribution transfer unit 23, respectively. Different transfer pulses φH1a and φH1b are applied to the first horizontal transfer electrode 24 and the second horizontal transfer electrode 25, respectively. Moreover, transfer pulses having the same phase and the same voltage are applied to the first horizontal transfer electrode 24 and the second horizontal transfer electrode 25 when horizontally transferring the signal charges. Moreover, to transfer the signal charges between the first horizontal transfer unit 21 and the second horizontal transfer unit 22 via the distribution transfer unit 23, it is required to establish a potential difference, and therefore different transfer pulses are applied to the first horizontal transfer electrode 24 and the second horizontal transfer electrode 25.

The horizontal transfer electrodes 14 are shared between the first horizontal transfer unit 21 and the second horizontal transfer unit 22, and φH2, φH3, and φH4 are applied to the horizontal transfer electrodes 14. Meanwhile, φHHT is applied to the distribution transfer electrode 26. The transfer control unit 6 is configured in units of four columns (from the left, the column L, a column CL, a column CR, and the column R). φST-L, φST-CL, and φST-R are applied to three signal charge storage electrodes 7 included in a unit of the transfer control unit 6 in order starting from a leftmost signal charge storage electrode in the unit. Moreover, φHLD-L, φHLD-CL, and φHLD-R are applied to three transfer blocking electrodes 8 included in a unit of the transfer control unit 6 in order starting from a leftmost transfer blocking electrode in the unit. Moreover, in the embodiment 5, a transfer pulse φVx which is the same pulse applied to the pixel repetition unit 5 is applied to the electrode on the column CR of the transfer control unit 6 as shown in the embodiment 3.

In the solid-state imaging device 62 according to the embodiment 5 of the present invention, four horizontal transfer electrodes 14 included in a packet correspond to four columns of the first vertical transfer units 1. That is, the solid-state imaging device 62 has a horizontal 4:1 interlace structure in which a line of signals are separated for every four signals and transferred.

Here, to generate data which corresponds to full HD videos and has (1920×1080) pixels using the structure and drive described in the embodiment 1 where the 3-pixel summing is performed in the horizontal direction, 5,760 pixels are required in the horizontal direction. Moreover, to support an aspect ratio 4:3 employed in digital still cameras, 4,320 pixels are required in the vertical direction. Thus, a total of about 25M pixels are required. However, the currently prevailing number of pixels is about 12M pixels to about 16M pixels, and thus the horizontal 2-pixel mixing is commonly used. Thus, the horizontal 2-pixel summing will be described for the case of outputting video in the present embodiment.

In the case of the horizontal 4:1 interlace, horizontal transfer is required four times if there is one horizontal transfer unit 2. On the other hand, in the solid-state imaging device 62 according to the embodiment 5, two horizontal transfer units are provided in parallel, and thus a line of the signal charges can be outputted by performing the horizontal transfer twice. Moreover, since two horizontal transfer units are provided in parallel, a line of the signal charges can be outputted by performing the horizontal transfer once in the case of the horizontal 2-pixel summing.

As described above, the solid-state imaging device 62 operating in the horizontally interlaced manner allows an increased length in the transfer direction of the horizontal transfer electrode. Furthermore, unlike in the two-phase drive conventionally used, the four-phase drive is applied to the solid-state imaging device 62, and therefore it is not necessary to form a barrier region below each horizontal transfer electrode. This allows the signal charges to be stored in all regions below the horizontal transfer electrodes. Thus, the widths of the horizontal transfer units 2 necessary to ensure the handling quantity of electric charges can be reduced. In particular, in the solid-state imaging device 62, the reduction of the widths of the first horizontal transfer units 21 is advantageous in facilitating the transfer of the signal charges from the first horizontal transfer unit 21 to the distribution transfer unit 23. Furthermore, the capacitance of the horizontal transfer electrode can largely be reduced. Thus, the solid-state imaging device 62 allows the reduction in capacitance of the horizontal transfer electrodes, reduction in voltage due to the use of the four-phase drive, and suppression of the increase in horizontal transfer frequency due to the use of parallel output, thereby achieving the low power consumption.

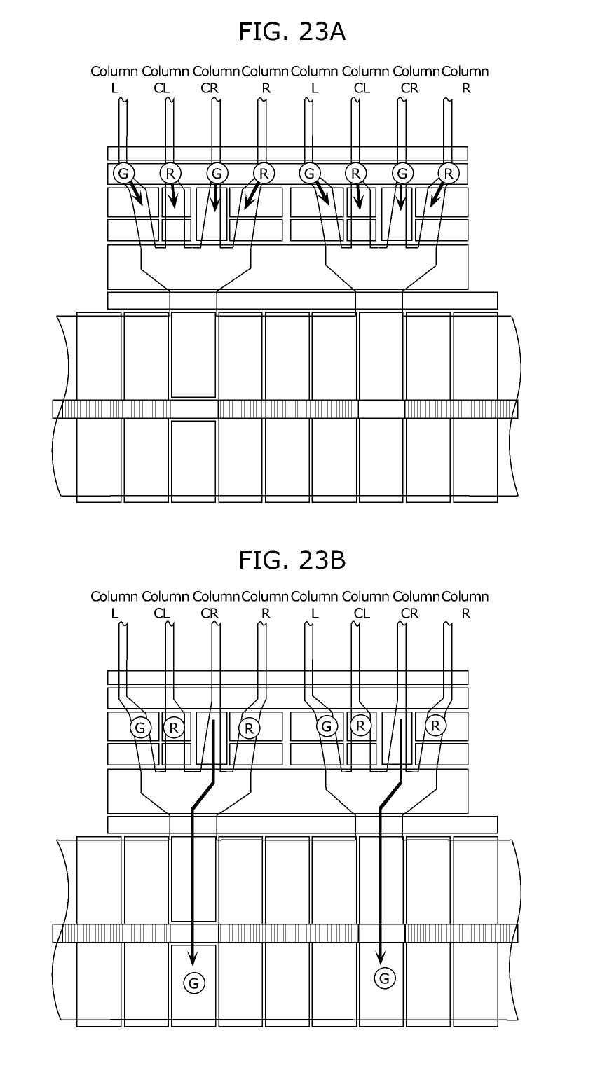

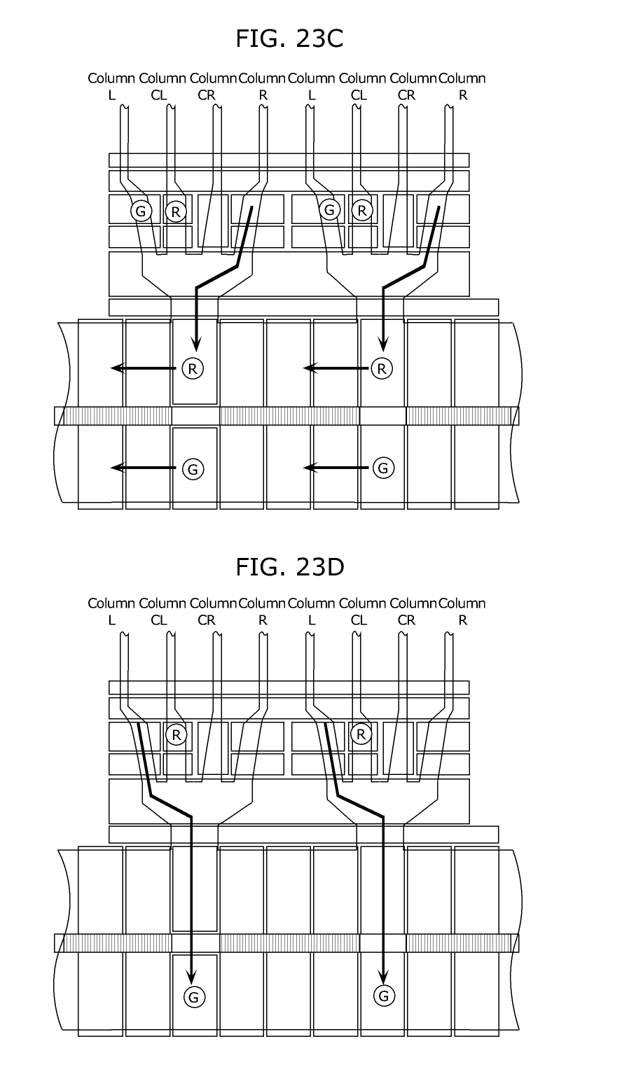

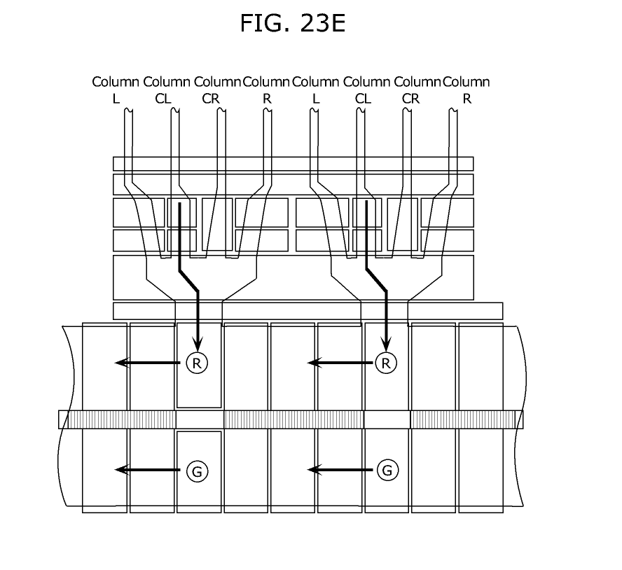

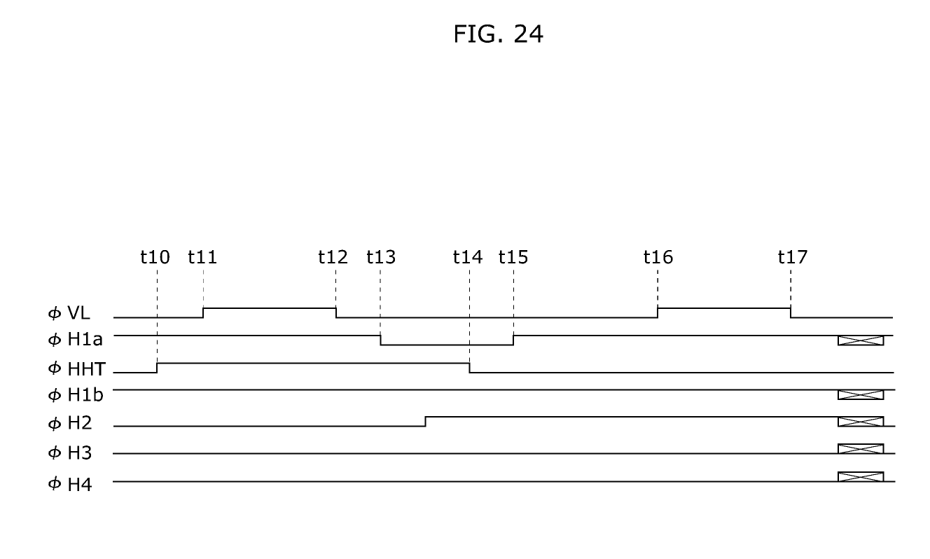

FIG. 23A to FIG. 23E are diagrams showing how the signal charges are transferred by the solid-state imaging device 62 in the normal mode. FIG. 24 is a diagram showing drive timing regarding the distribution transfer between the horizontal transfer units. FIG. 24 shows timing of the transfer pulses in the horizontal blanking period that are applied from the vertical final electrode 13 to electrodes of the first horizontal transfer unit 21, the distribution transfer unit 23, and the second horizontal transfer unit 22.

As shown in FIG. 23A to FIG. 23E, the number of packets of the first horizontal transfer unit 21 and the second horizontal transfer unit 22 in the normal mode is ¼ of the number of columns of the first vertical transfer units 1. Due to this, the solid-state imaging device 62 transfers the signal charges from the first vertical transfer units 1 to the transfer control unit 6 (FIG. 23A), and then transfers the signal charges to the first horizontal transfer unit 21 via the transfer control unit 6 and the second vertical transfer unit 9 in order starting from the column CR, the column R, the column L, and the column CL, for example.

The signal charges on the column CR are transferred to the first horizontal transfer unit 21 and further transferred from the first horizontal transfer unit 21 to the second horizontal transfer unit 22 via the distribution transfer unit 23 (FIG. 23B). Here, by applying a middle level voltage and a low level voltage to the signal charge storage electrode 7 and the transfer blocking electrode 8, respectively, on each column in the transfer control unit 6, the signal charges on the column R, the column L, and the column CL are retained by a corresponding signal charge storage electrode 7. Thus, the signal charges on the column R, the column L, and the column CL are not transferred to the first horizontal transfer unit 21.

Next, the solid-state imaging device 62 transfers the signal charges on the column R to the first horizontal transfer unit 21 and then performs the first horizontal transfer of the signal charges to the output amplifier (FIG. 23C). Moreover, the signal charges on the columns L and CL that are not transferred to the first horizontal transfer unit 21 are selectively blocked in the transfer control unit 6 from being transferred in the similar manner as with the signal charges on the column CR.

Then, the solid-state imaging device 62 transfers the signal charges on the column L to the first horizontal transfer unit 21, and further transfers the signal charges from the first horizontal transfer unit 21 to the second horizontal transfer unit 22 via the distribution transfer unit 23 (FIG. 23D). Then, the solid-state imaging device 62 transfers the signal charges on the column CL to the first horizontal transfer unit 21, and then performs the second horizontal transfer of the signal charges to the output amplifier. In this manner, the solid-state imaging device 62 outputs a line of the signal charges (FIG. 23E). Moreover, the remaining signal charges can also be outputted sequentially by the same operation.

Next, the distribution transfer between the horizontal transfer units shown in FIG. 24 will be described.

In the first horizontal transfer unit 21, the first horizontal transfer electrode 24 to which φH1a is applied receives the signal charges transferred from the vertical final electrode 13. Thus, in the horizontal blanking period, φH1a is first brought to the high level, and then φVL which is applied to the vertical final electrode 13 is brought to the middle level at a time t11. That is, it is desirable that φHHT which is applied to the distribution transfer electrode 26 is brought to the high level and φH1b which is applied to the second horizontal transfer electrode 25 is brought to also the high level at a time t10 which is prior to a time (the time t11) at which the signal charges are transferred below the vertical final electrode 13 from an imaging unit side. This forms a transfer path to the second horizontal transfer electrode 25 for the signal charges by a time (the time t11) at which the vertical final electrode 13 has been brought to the middle level.

Then, by sequentially bringing φVL, φH1a, and φHHT to the low level at a time t12, a time t13, and a time t14, respectively, the signal charges are transferred below the second horizontal transfer electrode 25 to which φH1b remaining at the high level is being applied. This is the end of the operation of transferring the signal charges from the vertical final electrode 13 to the second horizontal transfer unit 22.

The transfer pulse φHHT applied to the distribution transfer electrode 26 remains at the low level even in the subsequent horizontal transfer period. This prevents the signal charges transferred to the second horizontal transfer unit 22 from mixing with the signal charges to be transferred subsequently from the vertical final electrode 13 to the first horizontal transfer unit 21.

Moreover, φH1a applied to the first horizontal transfer electrode 24 which receives again the signal charges is transitioned to the high level at a time t15, φVL applied to the vertical final electrode 13 is transitioned to the middle level at a time t16, and then φVL is transitioned to the low level at a time t17. This is the end of the operation of transferring the signal charges from the vertical final electrode 13 to the first horizontal transfer unit 21. Moreover, the solid-state imaging device 62 thereafter transfers the signal charges horizontally.

Moreover, as shown in FIG. 23A to FIG. 23E, the above-described operation is performed twice in the normal mode.

Next, an operation of the solid-state imaging device 62 in the video mode will be described.

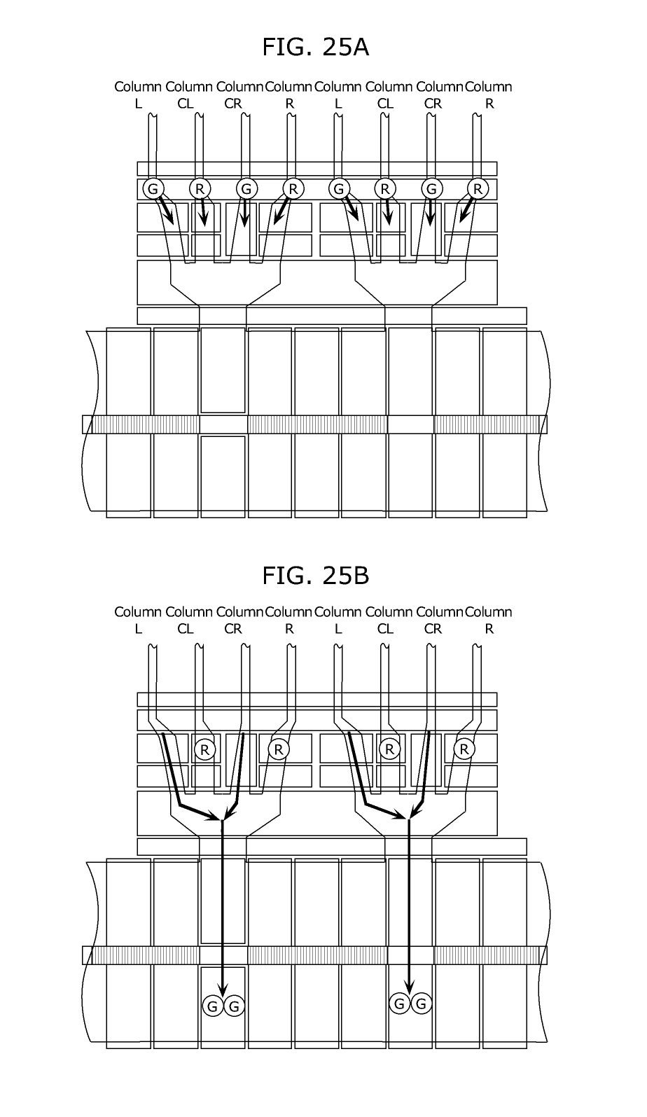

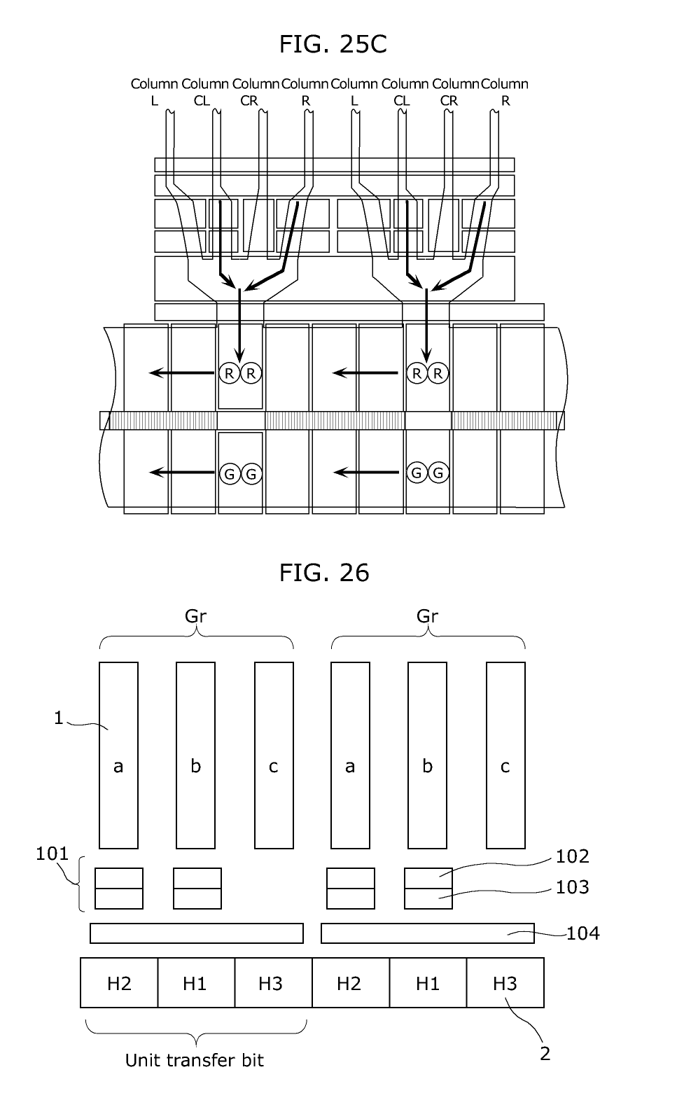

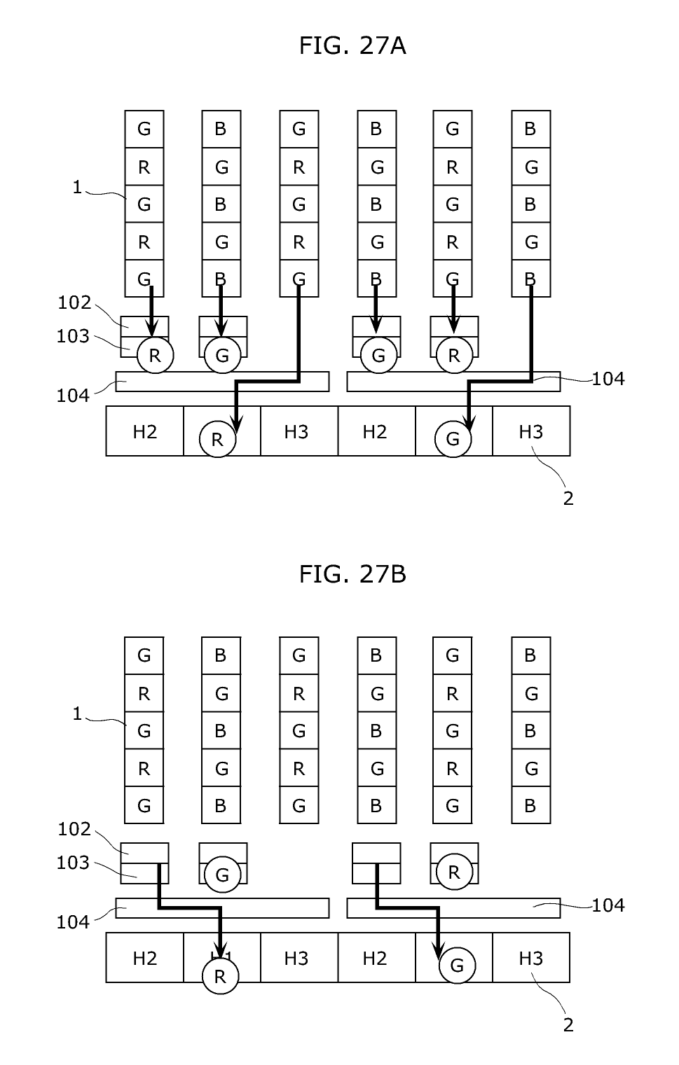

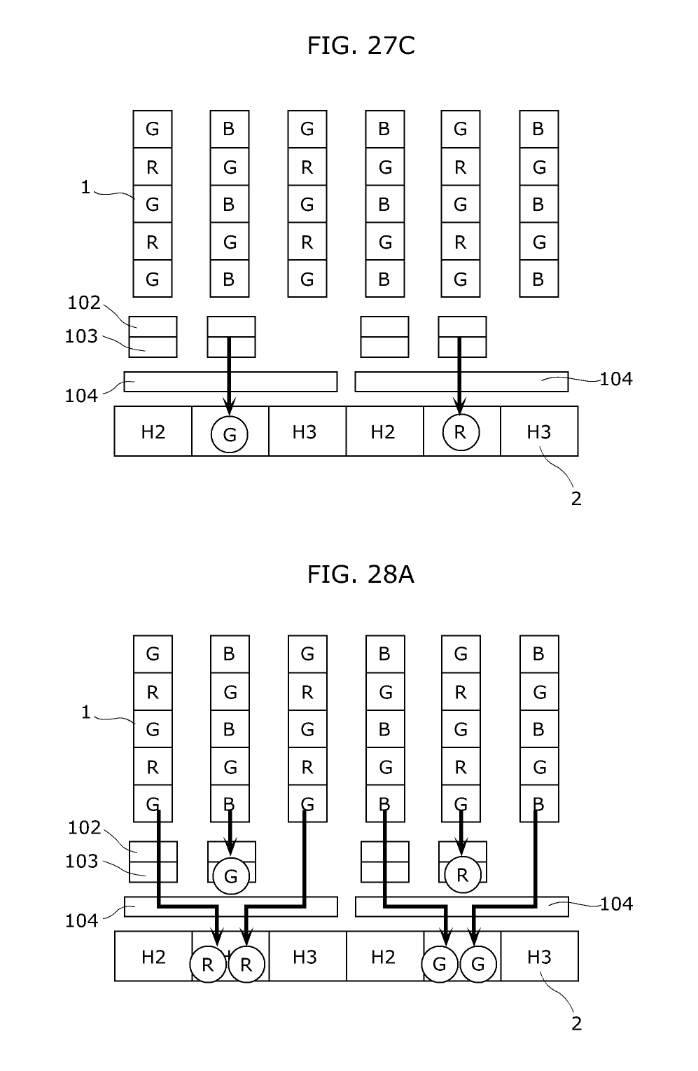

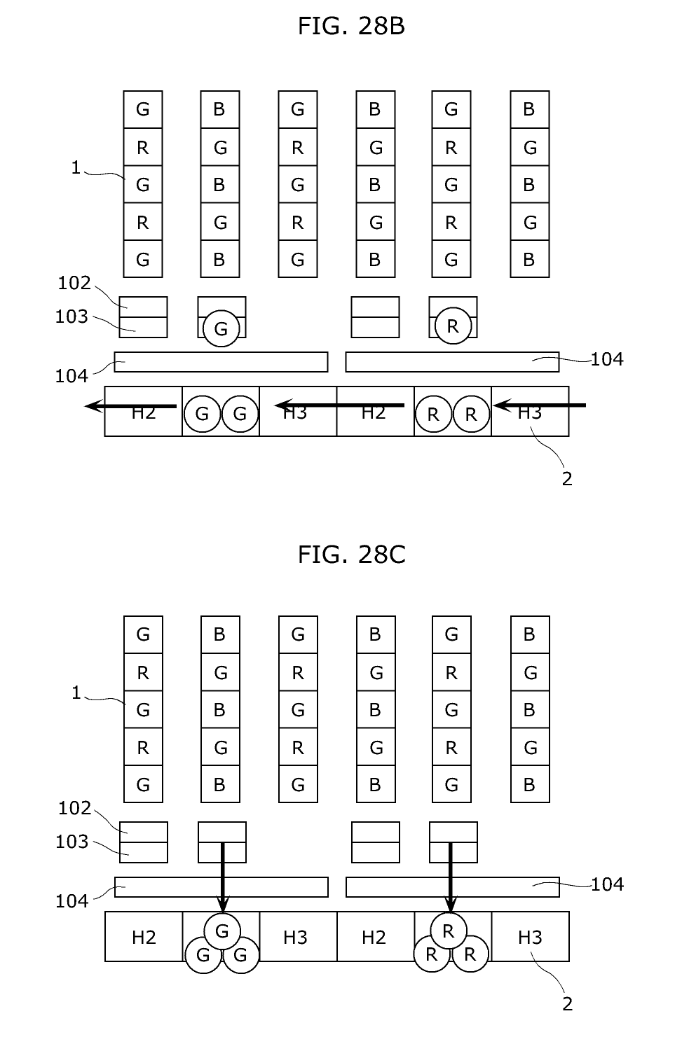

FIG. 25A to FIG. 25C are diagrams showing how the signal charges are transferred by the solid-state imaging device 62 in the video mode. The transfer operation between the first horizontal transfer unit 21 and the second horizontal transfer unit 22 is performed in the same manner as in the normal mode, but is performed once which is different from the operation in the normal mode.

The solid-state imaging device 62 in the video mode performs the 2-pixel summing on the signal charges which are adjacent to each other in the horizontal direction and have a same color.

First, as shown in FIG. 25A, the signal charges are transferred to the transfer control unit 6. Next, as shown in FIG. 25B, the signal charges on the columns CR and L are transferred to the second vertical transfer unit 9 via the transfer control unit 6 and summed. Moreover, the summed signal charges are transferred to the first horizontal transfer unit 21. On the other hand, the signal charges on the columns R and CL are retained below the signal charge storage electrode 7 without being transferred to the second vertical transfer unit 9, by bringing the signal charge storage electrode 7 and the transfer blocking electrode 8 on each of the columns R and CL to the middle level and the low level, respectively.

Moreover, the signal charges obtained by summing the signal charges on the columns CR and L that have been transferred to the first horizontal transfer unit 21 are transferred to the second horizontal transfer unit 22 via the distribution transfer unit 23.

Next, as shown in FIG. 25C, the signal charges on the columns R and CL are transferred from the signal charge storage electrode 7 to the second vertical transfer unit 9 and summed. Moreover, the summed signal charges are transferred to the first horizontal transfer unit 21.

The operation performed as described above is the end of summing, in the horizontal direction, two pixels having a same color. Then, the signal charges are transferred horizontally once to sequentially output to the output amplifier a line of the signal charges obtained by summing the two horizontal pixels.

As described above, the solid-state imaging device 62 according to the embodiment 5 of the present invention can reduce the inter-capacitance between the horizontal transfer electrodes by operating in the horizontally interlaced manner, and suppress the increase of the horizontal transfer frequency by transferring the signal changes in parallel using two horizontal transfer units. Furthermore, by employing the four-phase drive, the solid-state imaging device 62 can reduce the width of the horizontal transfer units and drive the horizontal transfer units at low voltages, thereby achieving the low power consumption. Furthermore, the solid-state imaging device 62 can support videos having a large number of pixels and reduce the transfer failure between the horizontal transfer units.

Moreover, the solid-state imaging device according to the embodiments 1 to 5 is implemented as an LSI which is an integrated circuit.

The solid-state imaging device according to the embodiments of the present invention has been described above. The present invention, however, is not limited to the embodiments described above.

For example, while corners and sides of each component are depicted in a linear manner in the figures, for manufacturing reasons, components having rounded corners and rounded lines are also included in the present invention.

Moreover, at least part of the functionality of the solid-state imaging devices according to the embodiments 1 to 5 and part of the functionality of each modification may be combined.

Moreover, numerals used in the above are merely illustrative for specifically describing the present invention and the present invention is not limited thereto.

Moreover, the present invention may be implemented as a camera such as digital still cameras or digital video cameras which includes any of the solid-state imaging devices according to the embodiments 1 to 5 and the modification thereof.

Moreover, the present invention may be implemented as a solid-state imaging device driving method for driving the solid-state imaging devices according to the embodiments 1 to 5, and the modification thereof.

### INDUSTRIAL APPLICABILITY

The present invention is applicable to solid-state imaging devices and is useful in particular as solid-state imaging devices for digital still cameras.

1. A solid-state imaging device comprising:
photoelectric conversion units disposed in rows and columns and configured to convert light into signal charges;
first vertical transfer units disposed in one-to-one correspondence with the columns and each configured to transfer in a vertical direction the signal charges obtained by said photoelectric conversion units converting the light, said photoelectric conversion units being disposed on a corresponding one of the columns; and
transfer control units disposed in correspondence with said first vertical transfer units on m columns successive in a horizontal direction, where m is an integer greater than or equal to 2, and each configured to selectively transfer the signal charges transferred by any of said corresponding first vertical transfer units on the m columns;
second vertical transfer units disposed in correspondence with said transfer control units and each configured to transfer the signal charges transferred by a corresponding one of said transfer control units; and
a horizontal transfer unit configured to transfer in the horizontal direction the signal charges transferred by said second vertical transfer units,
wherein each of said second vertical transfer units is disposed for two or more horizontal transfer electrodes forming a transfer packet of said horizontal transfer unit and has a region in which a transfer width tapers from said corresponding one of said transfer control units toward said horizontal transfer unit, and
each of said second vertical transfer units is provided with a vertical transfer electrode independent of vertical transfer electrodes of said first vertical transfer units and said transfer control units.

2. The solid-state imaging device according to claim 1,
wherein each of said transfer control units includes m of third vertical transfer units disposed in one-to-one correspondence with the m columns and each configured to transfer the signal charges transferred by said vertical transfer unit on a corresponding one of the m columns, and
a distance, in the horizontal direction, between centers of m of said third vertical transfer units disposed adjacent to one another is shorter than a distance, in the horizontal direction, between centers of said first vertical transfer units disposed adjacent to one another.

3. The solid-state imaging device according to claim 1,
wherein each of said second vertical transfer units includes:
a fourth vertical transfer unit configured to transfer the signal charges transferred by a corresponding one of said transfer control units and having a region in which a transfer width tapers from said corresponding one of said transfer control units toward said horizontal transfer unit; and
a fifth vertical transfer unit configured to transfer to said horizontal transfer unit the signal charges transferred by said fourth vertical transfer unit and having a constant transfer width, and
vertical transfer electrodes independent of each other are disposed above said fourth vertical transfer unit and said fifth vertical transfer unit.

4. The solid-state imaging device according to claim 1,
wherein each of said transfer control units includes m of third vertical transfer units disposed in one-to-one correspondence with the m columns and each configured to transfer the signal charges transferred by said vertical transfer unit on a corresponding one of the m columns,
a sixth vertical transfer unit which is one of said third vertical transfer units on the m columns includes a first vertical transfer electrode to which a same transfer pulse as a pulse applied to any of the vertical transfer electrodes of said first vertical transfer units is applied, and
m−1 of said third vertical transfer units other than said sixth vertical transfer unit included in said third vertical transfer units on the m columns each include a signal charge storage electrode and a transfer blocking electrode which are independent of the vertical transfer electrodes of said first vertical transfer units and said second vertical transfer units.

5. The solid-state imaging device according to claim 4,
wherein said sixth vertical transfer unit includes the first vertical transfer electrode only.

6. The solid-state imaging device according to claim 5,
wherein a transfer width of an entire region below the first vertical transfer electrode of said sixth vertical transfer unit increases from said corresponding one of said first vertical transfer units toward a corresponding one of said second vertical transfer units.

7. The solid-state imaging device according to claim 1,
wherein a maximum transfer width of each of said second vertical transfer units is larger than a width between outermost end portions of said first vertical transfer units disposed on outermost columns of the m columns.

8. The solid-state imaging device according to claim 1,
wherein each of said first vertical transfer units includes a first n-type impurities-doped region and a second n-type impurities-doped region,
the first n-type impurities-doped region is formed in each of said first vertical transfer units, each of said transfer control units, each of said transfer control units, and said horizontal transfer unit, and
the second n-type impurities-doped region is formed in each of said first vertical transfer units and each of said transfer control units and is not formed in each of said second vertical transfer units and said horizontal transfer unit.

9. The solid-state imaging device according to claim 1,
wherein a potential step is formed in each of said second vertical transfer units so that electric potential on a side of a corresponding one of said transfer control units is shallower than electric potential on a side of said horizontal transfer unit.

10. The solid-state imaging device according to claim 9,
wherein a third n-type impurities-doped region is formed in each of said second vertical transfer units on a side of said horizontal transfer unit to form the potential step.

11. The solid-state imaging device according to claim 9,
wherein a p-type impurities-doped region is formed in each of said second vertical transfer units on a side of a corresponding one of said transfer control units to form the potential step.

12. The solid-state imaging device according to claim 11,
wherein a third n-type impurities-doped region is further formed in each of said second vertical transfer units.

13. The solid-state imaging device according to claim 1,
wherein a p-type impurities-doped region is formed in each of said transfer control units.

14. The solid-state imaging device according to claim 1,
wherein first vertical transfer electrodes of said first vertical transfer units, said transfer control units, and said second vertical transfer units, and the two or more horizontal transfer electrodes of said horizontal transfer unit are formed of a single layer.

15. A method for driving a solid-state imaging device, said method comprising
during a period for which signal charges on one of m columns are horizontally transferred, transferring to a fourth vertical transfer unit the signal charges on other column of the m columns from a transfer control unit corresponding to the other column,
wherein said method is a method for driving the solid-state imaging device according to claim 3.

16. The method for driving the solid-state imaging device according to claim 15, said method comprising:
transferring to the fourth vertical transfer unit the signal charges on a center column, among the m columns, from the transfer control unit corresponding to the center column during a horizontal blanking period; and
during a period for which the signal charges on the center column are transferred, transferring to the fourth vertical transfer unit the signal charges on an outermost column, among the m columns, from the transfer control unit corresponding to the outermost column.

17. A camera comprising the solid-state imaging device according to claim 1.
